(19) United States
(12) Patent Application Publication
(10) Pub. No.: US 2026/0288007 A1
(43) Pub. Date: Sep. 24, 2026

(54) NON-PFAS-CONTAINING SURFACTANT COMPOSITIONS

(71) Applicant: Brewer Science, Inc., Rolla, MO (US)

(72) Inventor: Daniel Patrick Sweat, Rolla, MO (US)

(21) Appl. No.: 19/574,722

(22) Filed: Mar. 23, 2026

Related U.S. Application Data
(60) Provisional application No. 63/775,641, filed on Mar. 21, 2025.

(51) Int. Cl. G03F 7/11; C08G 83/00; H10W 70/695

(52) U.S. Cl. CPC G03F 7/11; C08G 83/003; H10W 70/695

(57) ABSTRACT

Minimizing total thickness variation in a spin-coated film often requires the use of a component that is, or behaves as, a surfactant, particularly as the thickness of the film increases to hundreds of nanometers and beyond. Currently, many commercially important surfactants used to improve coat quality are considered PFAS materials and are being phased out of materials. A set of new PFAS-free surfactants has been synthesized and tested for efficacy in improving coat quality. The surfactants comprise a central core molecule grafted with at least two recurring monomers that are different from the central core.

### CROSS-REFERENCE TO RELATED APPLICATIONS

The present application claims the priority benefit of U.S. Provisional Patent Application Ser. No. 63/775,641, filed Mar. 21, 2025, entitled NON-PFAS-CONTAINING SURFACTANT COMPOSITIONS, the entirety of which is incorporated by reference herein.

### BACKGROUND

### Field

The present invention relates broadly to compositions and methods of using those compositions in forming microelectronic structures.

### Description of Related Art

Surfactants generally consist of a hydrophobic group and a hydrophilic group, where “group” refers to either a single unit such as an acid or a combination of monomers into a polymer. Surfactants are often used to adjust the rheology, surface energy, and/or other material parameters that are important to control and optimize the coating quality of deposited films. The majority of surfactants that have been successfully used in spin-coated films to reduce/eliminate striations are generally based on functionalities based on perfluoroalkyl substances (PFAS). PFAS are loosely defined as any substances containing two or more fluorine atoms bound to a single carbon. However, PFAS have been widely recognized as an environmental hazard, and so PFAS-containing surfactants are widely being phased out of commercial and industrial materials. Non-PFAS and non-silicon-containing surfactants have proven unsuccessful in equaling the performance of PFAS-containing surfactants so far, so there is a need for new surfactant development.

### SUMMARY

In some embodiments, the present disclosure is broadly concerned with a method of forming a structure. The method comprises applying a composition on a surface of a substrate, or on one or more intermediate layers optionally present on the surface of the substrate, to form a layer of that composition. The composition comprises a star macromolecule dispersed or dissolved in a solvent system. The star macromolecule comprises a central core and at least two arms radiating from the central core, with the at least two arms each comprising at least two recurring monomers that are different from the central core. The central core is hydrophobic or hydrophilic. If the central core is hydrophobic, the at least two recurring monomers are hydrophilic. If the central core is hydrophilic, the at least two recurring monomers are hydrophobic. Additionally, at least one of (I), (II), (III), (IV), or (V) is true:
(I) the layer comprises about 50% by weight to about 99% by weight carbon, and further comprising:
   forming a hardmask layer on the layer;
   optionally forming one or more additional intermediate layers on the hardmask layer; and
   forming a photoresist layer on the one or more additional intermediate layers on the hardmask layer, if present, or on the hardmask layer if no additional intermediate layer is present;
(II) one or more intermediate layers is present and includes an uppermost intermediate layer that comprises a carbon-rich layer that comprises about 50% by weight to about 99% by weight carbon, and further comprising:
   optionally forming one or more additional intermediate layers on the layer; and
   forming a photoresist layer on the one or more additional intermediate layers on the layer, if present, or on the layer if no additional intermediate layer is present;
(III) further comprising:
   (a) (i) forming a carbon-rich layer that comprises about 50% by weight to about 99% by weight carbon on the layer;
      (ii) optionally forming one or more additional intermediate layers on the carbon-rich layer; and
      (iii) forming a photoresist layer on the one or more additional intermediate layers on the carbon-rich layer, if present, or on the carbon-rich layer if no additional intermediate layer is present;
   (b) (i) forming a hardmask layer on the layer;
      (ii) optionally forming one or more additional intermediate layers on the hardmask layer; and
      (iii) forming a photoresist layer on the one or more additional intermediate layers on the hardmask layer, if present, or on the hardmask layer if no additional intermediate layer is present; or
   (c) (i) forming a carbon-rich layer that comprises about 50% by weight to about 99% by weight carbon on the layer;
      (ii) forming a hardmask layer on the carbon-rich layer;
      (iii) optionally forming one or more additional intermediate layers on the hardmask layer; and
      (iv) forming a photoresist layer on the one or more additional intermediate layers on the hardmask layer, if present, or on the hardmask layer if no additional intermediate layer is present;
(IV) the surface of the substrate comprises a pattern comprising a plurality of gaps, and the applying a composition comprises depositing the composition in at least some of the gaps; or
(V) the one or more intermediate layers are present and include one or both of a carbon-rich layer that comprises about 50% by weight to about 99% by weight carbon or a hardmask layer, and further comprising forming a photoresist layer on the layer.

In other embodiments, a microelectronic structure is provided. The microelectronic structure comprises a substrate having a surface, there being one or more intermediate layers optionally present on the surface of the substrate. A layer is on the surface of the substrate, or on the one or more intermediate layers if present. The layer comprises a star macromolecule that comprises a central core and at least two arms radiating from the central core, with the least two arms each comprising at least two recurring monomers that are different from the central core. The central core is hydrophobic or hydrophilic. If the central core is hydrophobic, the at least two recurring monomers are hydrophilic. If the central core is hydrophilic, the at least two recurring monomers are hydrophobic. Additionally, at least one of (I), (II), (III), (IV), or (V) is true:
(I) the layer comprises about 50% by weight to about 99% by weight carbon;
   a hardmask layer is on the layer;
   one or more additional intermediate layers are optionally on the hardmask layer; and
   a photoresist layer is on the one or more additional intermediate layers on the hardmask layer, if present, or on the hardmask layer if no additional intermediate layer is present;
(II) one or more intermediate layers are present on the surface of the substrate and include an uppermost intermediate layer that comprises a carbon-rich layer comprising about 50% by weight to about 99% by weight carbon;
   optionally one or more additional intermediate layers on the layer; and
   a photoresist layer on the one or more additional intermediate layers on the layer, if present, or on the layer if no additional intermediate layer is present;
(III) further comprising:
   (a) (i) a carbon-rich layer that comprises about 50% by weight to about 99% by weight carbon is on the layer;
      (ii) one or more additional intermediate layers are optionally on the carbon-rich layer; and
      (iii) a photoresist layer is on the one or more additional intermediate layers on the carbon-rich layer, if present, or on the carbon-rich layer if no additional intermediate layer is present;
   (b) (i) a hardmask layer on the layer;
      (ii) one or more additional intermediate layers are optionally on the hardmask layer; and
      (iii) a photoresist layer is on the one or more additional intermediate layers on the hardmask layer, if present, or on the hardmask layer if no additional intermediate layer is present; or
   (c) (i) a carbon-rich layer that comprises about 50% by weight to about 99% by weight carbon on the layer;
      (ii) a hardmask layer on the carbon-rich layer;
      (iii) one or more additional intermediate layers on the hardmask layer; and
      (iv) a photoresist layer on the one or more additional intermediate layers on the hardmask layer, if present, or on the hardmask layer if no additional intermediate layer is present;
(IV) the surface of the substrate comprises a pattern comprising a plurality of gaps, and the layer is present in at least some of the gaps; or
(V) the one or more intermediate layers are present on the surface of the substrate and include one or both of a carbon-rich layer that comprises about 50% by weight to about 99% by weight carbon or a hardmask layer, and further comprising forming a photoresist layer on the layer.

In further embodiments, the disclosure provides a star macromolecule and compositions comprising the star macromolecule dispersed or dissolved in a solvent system. The star macromolecule comprises a central core and at least three arms radiating from the central core. The central core comprises an isocyanurate moiety, a double-branched chain alkane moiety, a multifunctional polyether moiety, or combinations thereof. Each of the at least three arms radiating from the central core comprises at least two recurring monomers that can be the same or different and that are chosen from pentafluorostyrene, isobornyl methacrylate, dicyclopentanyl methacrylate, tert-butylstyrene, methylstyrene, fluorostyrene, 3,5-difluorostyrene, 2-(ethoxyethoxy)ethyl acrylate, 2-methoxyacrylate, methyl acrylate, 2-(ethoxyethoxy)methyl acrylate, 2-methoxymethacrylate, methyl methacrylate, or combinations thereof.

### BRIEF DESCRIPTION OF THE DRAWINGS

FIG. 1 is an optical microscope image (500×) showing the presence of striations in a 1-μm comparative film (Example 4); and

FIG. 2 is an optical microscope image (500×) showing the lack of striations in a 1-μm film prepared according to one embodiment of the invention (Example 4).

### DETAILED DESCRIPTION

The present disclosure is broadly concerned with novel star macromolecules as well as compositions and methods utilizing those star macromolecules.

### Star Macromolecules

The star macromolecules disclosed herein comprises a central core and at least two arms radiating from the central core.

### 1. Central Core

Suitable central cores comprise a structure that allows a non-linear and/or star-shaped structure to be formed. For example, suitable central cores can be formed from starting central core compounds (described below) that comprise two or more reactive sites onto which the at least two radiating arms can be grafted. The central core can comprise a cyclic structure, which can be a single ring or polycyclic. Furthermore, the central core can comprise alicyclic, heterocyclic, and/or aromatic rings. In some embodiments, the central core can comprise a branched or hyperbranched alkyl moiety such as that found in central portion of pentaerythritol ethoxylate and/or trimethylolpropane tris[poly(propylene glycol), amine terminated]ether. The central core can be hydrophobic or hydrophilic, but in some preferred embodiments it is hydrophilic.

To determine if a central core or monomer (collectively referred to as “compound” for these purposes) is hydrophilic or hydrophobic, the compound is formed into a polymer including about 9 to about 90 recurring units of that compound. A formulation is prepared by dispersing or dissolving the formed polymer in a suitable solvent, preferably propylene glycol methyl ether acetate, at a level of about 1% to about 3% by weight formed polymer, with the balance being propylene glycol methyl ether acetate. The formulation is then spin coated onto a silicon wafer at 1,500 rpm and baked at 205° C. for 60 seconds. The surface contact angle of the film is then determined by averaging 5 measurements taken in different spots using a contact angle measurement tool, such as a VCA-3000S Wafer System (AST Products, Billerica, MA) contact angle measurement tool, with water as the droplet solvent. If the contact angle is less than or equal to 70°, the compound is considered to be hydrophilic. If the contact angle is greater than 70°, the compound is considered to be hydrophobic.

Examples of suitable central cores comprise an isocyanurate moiety (e.g., derived from triglycidyl isocyanurate, monoallyl diglycidyl isocyanurate, and/or tris(2-carboxyethyl)isocyanurate), a moiety of a double-branched chain alkane (preferably C₄-C₈; e.g., derived from a neopentane such as pentaerythritol ethoxylate and/or other pentaerythritol), a moiety of a branched, multifunctional (preferably trifunctional) polyether (e.g., derived from trimethylolpropane tris[poly(propylene glycol), amine terminated]ether), and/or a bisbenzeneamine such as N,N,N′,N′-tetraglycidyl-4,4′-methylenebisbenzenamine.

### 2. Arms

As noted previously, the star macromolecules have at least two arms radiating from the central core. In some embodiments, the star macromolecules have exactly two arms. In some embodiments, the star macromolecules have at least three arms. In some embodiments, the star macromolecules have exactly three arms. Each arm is polymeric, meaning that each arm comprises at least two recurring monomers. (As used herein, “oligomeric” and “polymeric” are both referred to as “polymeric” when discussing the arms unless specified otherwise.)

These monomers are different from the central core and can be the same monomer type or a different monomer type on each arm as well as between arms. The numbers of each monomer type could be identical among, or different between, two or more arms. For example, a first arm could be a copolymer (including a block copolymer), or it could be a homopolymer. A second arm could also be a copolymer (including a block copolymer) or a homopolymer, and that copolymer or homopolymer could be the same as, or different from, the copolymer or homopolymer of the first arm. It will be appreciated that this flexibility allows for the customization of the star molecules based on factors such as the central core that is selected, the type of composition in which the star molecules will be utilized, other components in that composition, customer needs, etc.

In some embodiments, if the central core is selected to be hydrophobic, one, two, three, or all of the arms preferably include recurring monomers (and preferably two or more such recurring monomers) that are hydrophilic. In one or more embodiments, if the central core is selected to be hydrophilic, one, two, three, or all of the arms preferably include recurring monomers (and preferably two or more such recurring monomers) that are hydrophobic. Whether a monomer or an arm is hydrophobic or hydrophilic is determined as described previously with respect to the central core.

In some embodiments, one, two, three, or all of the arms include at least one monomer that is hydrophilic and at least one monomer that is hydrophobic. In one or more embodiments, this arrangement can be random, while in other embodiments, this arrangement is accomplished by the use of a copolymer in the arm(s), with one block of the copolymer being hydrophobic and the other block being hydrophilic. In some preferred embodiments, the arms comprise a block copolymer, and the hydrophilic block is the interior block (i.e., the block closest to the central core), and the hydrophobic block is the exterior block (i.e., the block furthest from the central core). In other embodiments, the arms comprise a block copolymer, and the hydrophobic block is the interior block (i.e., the block closest to the central core), and the hydrophilic block is the exterior block (i.e., the block furthest from the central core.

In some embodiments, a hydrophobic block is one in which about 70% or more, preferably about 80% or more, more preferably about 90% or more, and even more preferably about 100% of the monomers are hydrophobic. Additionally or alternatively, in some embodiments, a hydrophilic block is one in which about 70% or more, preferably about 80% or more, more preferably about 90% or more, and even more preferably about 100% of the monomers are hydrophilic.

Regardless of whether the arms are homopolymers or copolymers, the number of recurring monomers on each arm can be selected based on some of the same factors as described above with respect to selecting of the monomer type. In some embodiments, the number of monomers on an arm can range from 2 to about 30, preferably about 4 to about 20, and more preferably about 6 to about 10.

In embodiments where two different types of monomers are included in the arm(s), the molar ratio of first monomer to second monomer is about 1:2 to about 2:1, more preferably about 1:1.7 to about 1.7:1, and even more preferably about 1:1.2 to about 1.2:1. In some embodiments where the arm(s) comprises a block copolymer with the foregoing first and second monomer ratios, the first monomer is the interior block, and the second monomer is the exterior block. In the same or different embodiments, the first monomer is hydrophilic and the second monomer is hydrophobic.

In some embodiments, the molar ratio of the first monomer (which is the only monomer in the instance of arms comprising homopolymers) to the central core compound in the star macromolecule is preferably about 2X:1 to about 10X:1, and more preferably about 5X:1 to 8X:1, where X represents the number of reactive sites on the starting central core compound. Reactive sites are those locations where reactive groups (e.g., epoxides, alcohols, amines, and/or carboxylic acids) were present on the starting central core compound before chain transfer or “CTA” grafting, as explained in more detail below. For example, when triglycidyl isocyanurate, which has 3 reactive sites (i.e., 3 epoxides), is used as the starting central core compound, the first monomer is preferably present at about 6 to about 30 moles, and more preferably from about 15 to about 24 moles per 1 mole of triglycidyl isocyanurate.

In copolymer embodiments, the molar ratio of the second monomer to the central core compound in the inventive star macromolecules is preferably about 2X:1 to about 30X:1, and more preferably about 5X:1 to 15X:1, where X again represents the number of reactive sites on the starting central core compound. Using triglycidyl isocyanurate as the exemplary central core compound again, the second monomer is preferably present at about 6 to about 90 moles, and preferably about 15 to about 45 moles per 1 mole of triglycidyl isocyanurate.

Regardless of the number of monomers, type of monomers, and/or the arrangement, exemplary hydrophobic monomers that can be used to form the arms are chosen from pentafluorostyrene, isobornyl methacrylate, dicyclopentanyl methacrylate, tert-butylstyrene, methylstyrene, fluorostyrene, 3,5-difluorostyrene, benzyl methacrylate, 2-ethylhexyl methacrylate, linear alkyl methacrylates (preferably C₃ or greater and more preferably C₃-C₁₈), or combinations thereof. Exemplary hydrophilic monomers are chosen from 2-(ethoxyethoxy)ethyl acrylate, 2-methoxyacrylate, methyl acrylate, 2-(ethoxyethoxy)methyl acrylate, 2-methoxymethacrylate, methyl methacrylate, poly(ethylene glycol)monomethyl ether methacrylate, poly(ethylene glycol) monomethyl ether acrylate, acrylic acid, methacrylic acid, 4-hydroxystyrene, 4-acetoxystyrene, or combinations thereof. In one or more embodiments, the star macromolecules are non-ionic.

In some preferred embodiments, at least some of the arms of the star macromolecules have at least a fragment of a chain transfer agent (CTA) at their ends. Chain transfer agents are used in some preferred methods of synthesis, described in detail below, and can remain at the ends of the arms of some embodiments of the final star macromolecules. Suitable chain transfer agents include, but are not limited to, (4-cyano-4-(((dodecylthio)carbonothioyl)thio)pentanoic acid, 4-cyano-4-(phenylcarbonothioylthio)-pentanoic acid, 2-(dodecylthiocarbonothioylthio)propanoic acid, (4-cyano-4-(((dodecylthio)-carbonothioyl)thio)pentanol, or combinations thereof.

Some preferred star macromolecules are chosen from one or more of

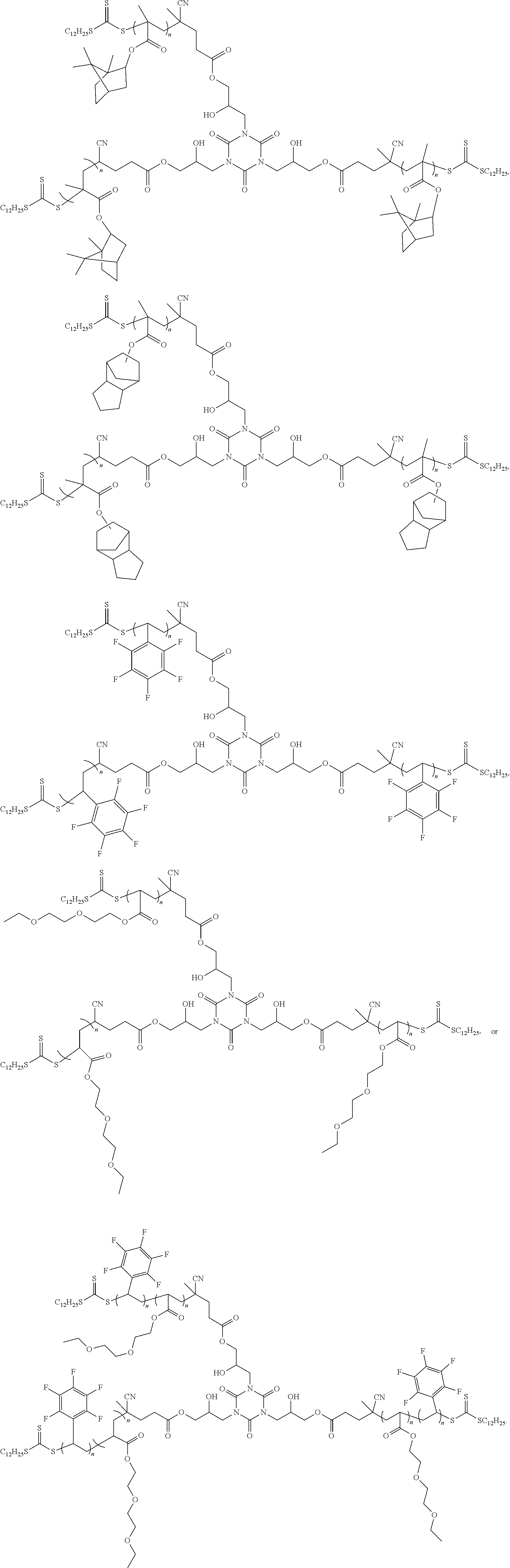

In some embodiments, each n is individually chosen from preferably 2 to about 30, more preferably about 4 to about 20, and still more preferably about 6 to about 10.

### 3. Synthesis of Star Macromolecules

The star macromolecules are suitably formed by grafting the previously described monomers to a starting central core compound. Suitable central core compounds are those that result in a central core as described previously. Central core compounds include the previously described cyclic and/or branched alkane groups and preferably include at least two, and preferably at least three, reactive groups. Examples of suitable reactive groups include epoxides, alcohols, amines, carboxylic acids, or combinations thereof. Examples of central core compounds for use herein includes isocyanurates (e.g., triglycidyl isocyanurate, monoallyl diglycidyl isocyanurate, and/or tris(2-carboxyethyl)isocyanurate), double-branched chain alkanes (preferably C₄-C₈; e.g., neopentanes such as pentaerythritol ethoxylate or other pentaerythritols), branched, multifunctional (preferably trifunctional) polyethers (e.g., trimethylolpropane tris[poly(propylene glycol), amine terminated]ether), and/or a bisbenzeneamine (e.g., N,N,N′,N′-tetraglycidyl-4,4′-methylenebisbenzenamine).

The monomers (the number and types of which can be selected as described previously) are preferably reacted with the central core compound using reversible addition fragmentation (RAFT) polymerization using a CTA. By using RAFT polymerization to extend the functional groups from the central core and thereby form the arms, the functional chains can be chain extended after the first polymerization to yield homopolymers or copolymers, as described previously. Advantageously, this allows the amount of hydrophilicity and hydrophobicity of the arms and/or segments within each arm to be more readily tailored by varying the degree of polymerization of the monomers, or of two blocks in the instance of a block copolymer. Although the primary function of the CTA is for synthesis, it will be understood that embodiments synthesized using RAFT polymerization typically contain at least a fragment of the CTA at the ends of at least some of the arms of the final star macromolecule, as described above.

In more detail, in some embodiments to synthesize the star macromolecule, the central core compound is first reacted with a CTA in the presence of a catalyst and solvent system, so as to attach the CTA to the reactive sites on the central core compound. Preferably, the reaction is performed under an inert atmosphere such as nitrogen. The reaction mixture typically has a total solids content of about 20% to about 55% by weight, and preferably about 35% to about 45% by weight, based upon the total weight of the reaction mixture taken as 100% by weight, with the remainder of the total reaction mixture being the solvent system.

The molar ratio of the CTA to the central core compound is preferably about X:1, where X is the number of reactive sites on the central core compound. For example, when triglycidyl isocyanurate is used as the central core molecule, X is 3 due to the number of reactive epoxy sites on triglycidyl isocyanurate. The reaction mixture is typically heated to a temperature of about 70° C. to about 125° C., and preferably about 100° C. to about 120° C. for a typical time period of about 16 hours to about 36 hours, and preferably about 20 hours to about 30 hours. The reaction mixture is then cooled and bottled for further use.

Suitable chain transfer agents for use in this reaction include, but are not limited to, (4-cyano-4-(((dodecylthio)carbonothioyl)thio)pentanoic acid, 4-cyano-4-(phenylcarbonothioylthio)-pentanoic acid, 2-(dodecylthiocarbonothioylthio)propanoic acid, (4-cyano-4-(((dodecylthio)-carbonothioyl)thio)pentanol, or combinations thereof.

Preferred solvent systems include a solvent selected from the group consisting of propylene glycol monomethyl ether acetate, propylene glycol methyl ether, cyclopentanone, cyclohexanone, toluene, anisole, and mixtures thereof. The solvent system is preferably utilized at a level of about 45% to about 80% by weight, and more preferably about 50% to about 70% by weight, based upon the total weight of the reaction mixture taken as 100% by weight.

Suitable catalysts include, but are not limited to, ethyltriphenylphosphonium bromide, tetrabutylphosphonium bromide, benzyltriethylammonium chloride, imidazole, pyridine, tetrabutylammonium bromide, tetrabutylammonium iodide, or combinations thereof. The catalyst is typically present in the reaction mixture at levels of about 1% to about 15% by weight, and preferably about 5% to about 10% by weight as a percentage of the total weight of the central core compound.

The following reaction scheme shows an exemplary reaction between a CTA ((4-cyano-4-(((dodecylthio)carbonothioyl)thio)pentanoic acid) and a central core compound (i.e., triglycidyl isocyanurate). The resulting CTA-grafted central core compound comprises a central core (i.e., moiety of triglycidyl isocyanurate) with respective CTA molecules bound to the three reactive sites (i.e., epoxides) of the starting central core compound.

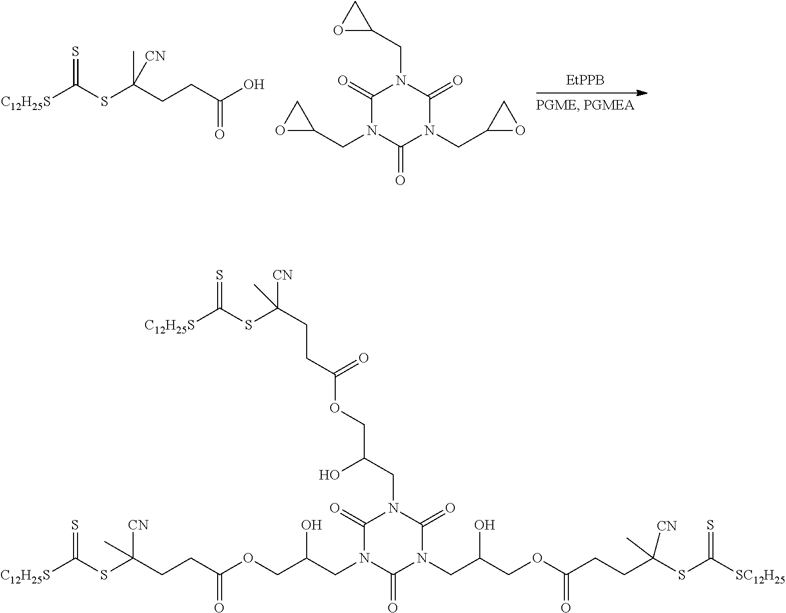

The next step in this embodiment of the synthesis process involves growing the polymers from the CTA-grafted arms created as described above. Again, the monomer types and numbers can be selected as described previously, and the polymers can be a homopolymer or a copolymer (random or block).

In more detail, the CTA-grafted central core compound, an initiator, the monomer (or monomers, if a random copolymer is being formed) to be polymerized (the “first monomer”), and optional additional solvent system are charged to a reactor, preferably in an inert atmosphere such as nitrogen. Suitable initiators for use in this polymerization reaction include, but are not limited to, azobisisobutyronitrile, 1,1′-azobis(cyclohexanecarbonitrile), 4,4′-azobis(4-cyanovaleric acid), benzoyl peroxide, dicumyl peroxide, or combinations thereof. The initiator is typically present in the reaction mixture at a level of about 0.1% to about 1%, by weight and preferably about 0.3% to about 0.8% by weight as a percentage of the total weight of the CTA-grafted central core compound.

The quantity of first monomer that is charged to the reaction system is dependent upon the desired characteristics of the final star molecule, but in some embodiments, the first monomer is present in the reaction mixture in a molar ratio relative to the CTA-grafted central core compound so that the first monomer is present at a level of about 2X to about 10X, and preferably about 5X to about 8X, where X represents the number of reactive sites on the original (i.e., ungrafted) central core compound. For example, when triglycidyl isocyanurate is used as the central core molecule, the first monomer is preferably present at about 6 to about 30 moles, and preferably at about 15 to about 24 moles per 1 mole of triglycidyl isocyanurate. The reaction mixture typically has a total solids content of about 20% to about 55%, and preferably about 35% to about 45%, based upon the total weight of the reaction mixture taken as 100% by weight, with the remainder of the total reaction mixture being the solvent system. The reaction mixture is generally heated to a temperature of about 50° C. to about 150° C., and preferably about 60° C. to about 110° C., typically for a time preferably of about 4 hours to about 36 hours, and preferably about 20 hours to about 30 hours. It will be appreciated that the reaction temperature depends on the first monomer utilized. The reaction mixture, which contains the formed first-monomer-grafted central core compound (which is the final star macromolecule for uses where arms containing block copolymers are not desired), is then cooled and may be bottled for further use or used as-is in a block copolymer synthesis step (described below). In some embodiments, the solvent system may be removed from the reaction mixture in order to leave only the solids for further use.

The following shows one embodiment of a polymerization reaction between the previously described CTA-grafted central core compound (i.e., (4-cyano-4-(((dodecylthio)carbonothioyl)thio)pentanoic acid) grafted to triglycidyl isocyanurate) and an exemplary first monomer (i.e., 2-(ethoxyethoxy)ethyl acrylate).

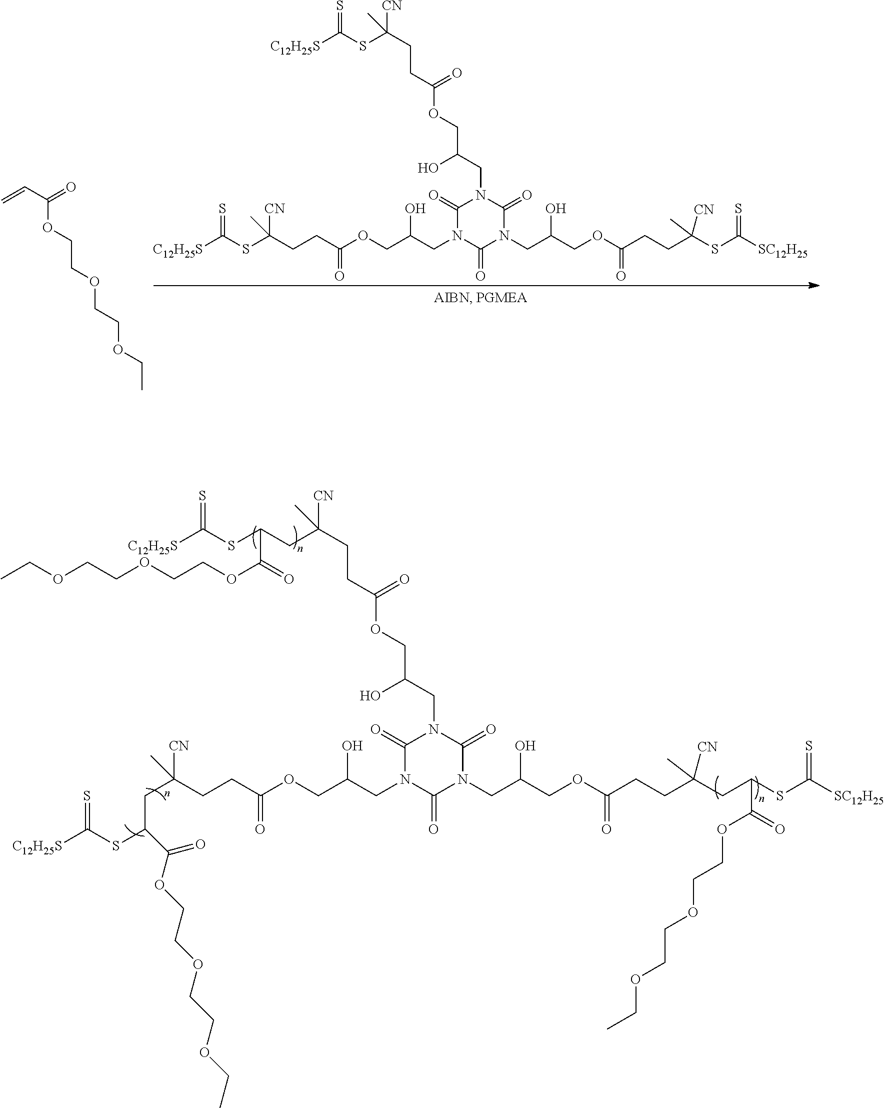

In embodiments where the arms are selected to be block copolymers, a second polymerization step is carried out to create the second block of the arms using a first-monomer-grafted central core compound prepared as described above. In this step, the first-monomer-grafted central core molecule, an initiator, the hydrophilic monomer or hydrophobic monomer (the “second monomer”), and optional additional solvent system are charged to a reactor, preferably in an inert atmosphere such as nitrogen. Suitable initiators include those described above. In this step, the initiator is typically present in the reaction mixture at a level of about 0.05% to about 5%, and preferably about 0.08% to about 2% by weight as a percentage of the total weight of the first-monomer-grafted central core compound.

The amount of second monomer that is charged to the reaction system is dependent upon the desired characteristics of the final star molecule, but in some embodiments having block copolymer arms, the second monomer is present in the reaction mixture in a molar ratio relative to the first-monomer-grafted central core compound so that the second monomer is included at a level of about 2X to about 30X, and preferably about 5X to about 15X, where X represents the number of reactive sites on the original (i.e., before CTA grafting) central core compound. For example, when triglycidyl isocyanurate is used as the central core compound, the second monomer is preferably present at about 6 to about 90 moles, and preferably about 15 to about 45 moles per 1 mole of triglycidyl isocyanurate. The reaction mixture typically has a total solids content of about 20% to about 55%, and preferably about 35% to about 45%, based upon the total weight of the reaction mixture taken as 100% by weight, with the remainder of the total reaction mixture being the solvent system. The reaction mixture is generally heated to a temperature of about 50° C. to about 150° C., and preferably about 60° C. to about 110° C. for a time of about 4 hours to about 36 hours, and preferably about 20 hours to about 30 hours. It will be appreciated that the reaction temperature depends on the second monomer utilized. The reaction mixture, which contains the central core moiety with at least two (preferably at least three) block copolymer arms (i.e., the star macromolecule), can be used immediately or bottled for future use. In some embodiments, the solvent system may be removed from the reaction mixture in order to leave only the solids for further use.

The following reaction scheme shows one embodiment of a polymerization reaction between the previously described first-monomer-grafted central core compound and an exemplary second monomer (i.e., pentafluorostyrene).

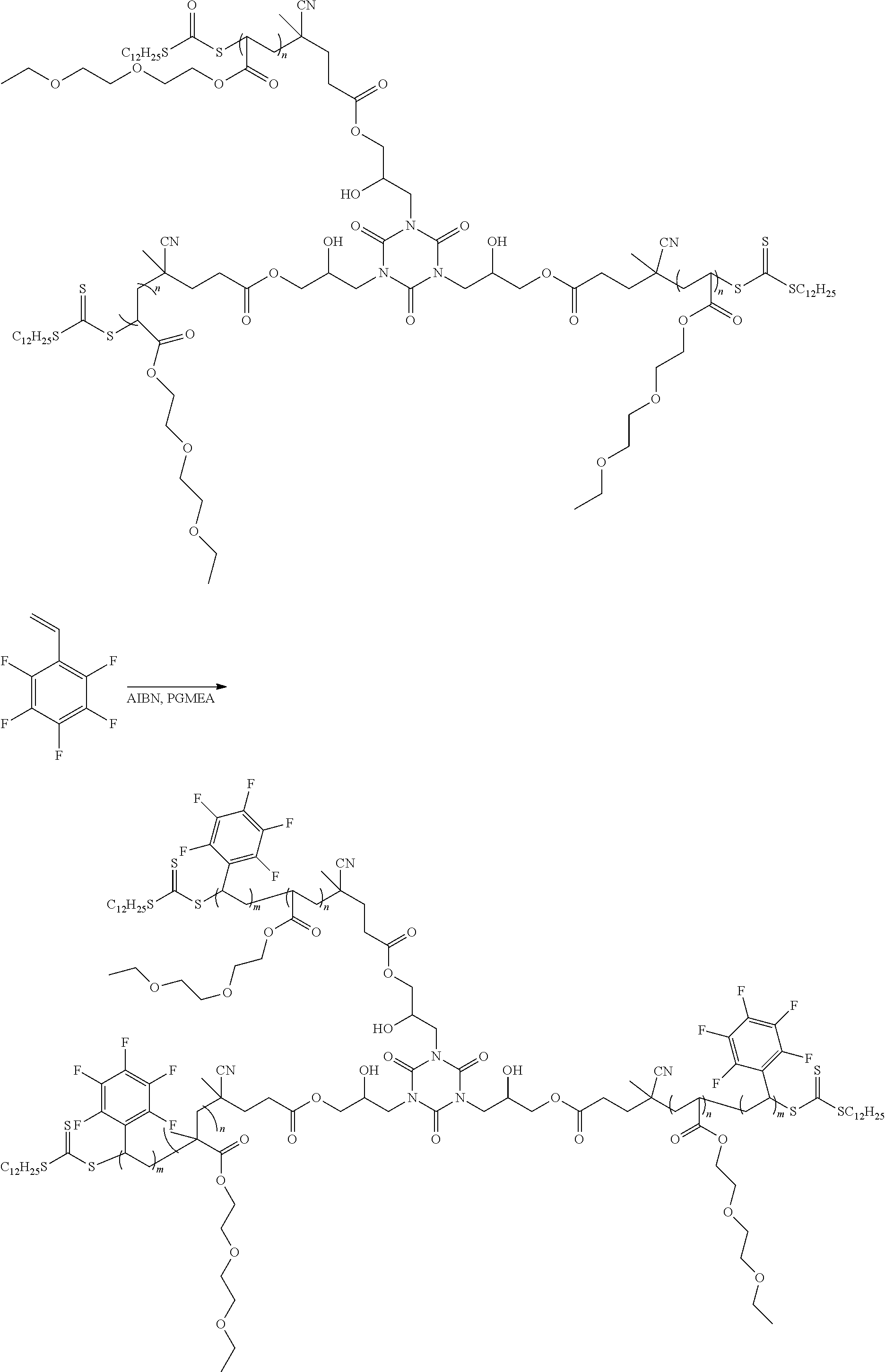

It will also be appreciated by those skilled in the art that the various steps in creating the final star macromolecule can be performed in the same or separate vessels for ease of manufacturing. That is, the molecular weight profile is similar for a multi-step synthesis and a “one-pot” synthesis. Typical weight-average molecular weights (Mw) (as measured by gel permeation chromatography) of the final star macromolecule are about 2,500 g/mol to about 25,000 g/mol, and preferably about 4,000 g/mol to about 15,000 g/mol.

In one or more embodiments, the star macromolecule is PFAS-free. As used herein, PFAS-free means that the star macromolecule does not include an alkyl that has two or more fluorine atoms bonded to the same carbon atom.

In some embodiments, the star macromolecule comprises less than about 0.1% by weight fluorine atoms, more preferably less than about 0.05% by weight fluorine atoms, and even more preferably about 0% by weight fluorine atoms.

Additionally or alternatively, some embodiments of the star macromolecule comprise less than about 0.1% by weight silicon atoms, more preferably less than about 0.05% by weight silicon atoms, and even more preferably about 0% by weight silicon atoms.

In the same or different embodiments, the star macromolecule comprises less than about 0.1% by weight iodine atoms, more preferably less than about 0.05% by weight iodine atoms, and even more preferably about 0% by weight iodine atoms.

In some embodiments, the star macromolecule does not include a metal phthalocyanine or moiety thereof.

### Lithography Underlayer Compositions with Star Macromolecule

It will be appreciated that the above-described star macromolecules can be used in any lithography composition in which a surfactant or similar component is needed. This can be accomplished by simply mixing star macromolecules as described above into the particular composition following the usual preparation procedure for that composition.

For example, the star macromolecules described herein can be used in the compositions of the following commonly-owned patents and published patent applications, the contents of which are each hereby incorporated by reference: U.S. Pat. No. 7,833,692 (Amine-arresting additives for materials used in photolithographic processes); U.S. Pat. No. 8,895,230 (Spin-on carbon compositions for lithographic processing); U.S. Pat. No. 9,496,164 (Cyclic olefin polymer compositions and polysiloxane release layers for use in temporary wafer bonding processes); U.S. Pat. No. 12,024,594 (Multifunctional materials for temporary bonding); U.S. Pat. No. 12,482,656 (Coating compositions and methods to enhance SC-1 resistance); US 20220195238 (Chemically homogeneous silicon hardmasks for lithography); US20240030063 (Thermally decomposable fill material); US 20240280905 (Underlayer and methods for EUV lithography); US 20250293030 (Solubility switch topographic fill materials and methods), and US 20250208517 (Acidic spin-on carbon (SOC) layer for EUV lithography), all of which are owned by Brewer Science, Inc.

Regardless of the embodiment, the lithography underlayer compositions preferably comprise the above-described star macromolecules and an underlayer-forming compound (monomer, oligomer, and/or polymer) dispersed or dissolved in a solvent system. The lithography underlayer composition may also comprise optional ingredients such as those chosen from acid generators, crosslinkers, polymers, catalysts, additives, or mixtures thereof.

Suitable polymers for use as the underlayer-forming compound include carbon-rich polymers, such as those chosen from polystyrene, functionalized polystyrene derivatives (e.g., poly(4-methylstyrene), poly(vinyl naphthalene)), polysulfones, polyethersulfones, poly(ether ether ketone), polycarbonates, epoxies, novolacs, polyimides, or combinations thereof.

In some embodiments, suitable polymers and/or oligomers for use as the compound comprise monomers chosen from phenolic compounds, styrene, styrene-containing compounds, glycidyl-containing compounds, 2-hydroxyethyl methacrylate, hydroxypropyl methacrylate, hydroxybutylacrylate, silanes, siloxanes, or combinations thereof.

In the same or different embodiments, the underlayer-forming compound can be a monomeric compound, such as those chosen from phenolic compounds, styrene, styrene-containing compounds, glycidyl-containing compounds, 2-hydroxyethyl methacrylate, hydroxypropyl methacrylate, hydroxybutylacrylate, silanes (e.g., 2-(3,4-epoxycyclohexyl)ethyltrimethoxysilane), or combinations thereof.

Additionally, the underlayer-forming compound can be functionalized with light absorbing or other moieties (e.g., 9-anthracenecarboxylic acid).

Regardless of the selected underlayer-forming compound (i.e., monomer, oligomer, and/or polymer), that compound is typically present in the composition at levels of about 1% by weight to about 30% by weight, more preferably about 3% by weight to about 10% by weight, and even more preferably about 4% by weight to about 7% by weight, based upon the total weight of the composition taken as 100% by weight.

The star macromolecule is preferably present in the composition at levels of about 0.001% by weight to about 1% by weight, and more preferably about 0.01% by weight to about 0.1% by weight, based upon the total weight of the compound (i.e., monomer, oligomer, and/or polymer) taken as 100% by weight.

The star macromolecule may be used alone or in conjunction with other surfactant-type components (also preferably non-PFAS-containing) to create the same effect as using the inventive star macromolecules. In some embodiments, the composition does not include any surfactants other than the inventive star macromolecule.

The above ingredients are mixed in a solvent system to form the particular composition. Preferred solvent systems include one or more solvents chosen from propylene glycol methyl ether acetate, propylene glycol methyl ether, propylene glycol ethyl ether, cyclopentanone, cyclohexanone, anisole, acetophenone, or mixtures thereof. The solvent system is preferably utilized at a level of about 80% by weight to about 99% by weight, more preferably about 85% by weight to about 97% by weight, and even more preferably about 92% by weight to about 95% by weight, based upon the total weight of the lithography underlayer composition taken as 100% by weight. The material is preferably filtered before use, such as with a 0.1-μm or 0.2-μm PTFE filter.

In embodiments where the star macromolecule is incorporated into a carbon-rich layer (e.g., spin-on carbon layer, or “SOC”), the composition to form that layer preferably comprises about 50% by weight or greater carbon, preferably about 50% by weight to about 99% by weight carbon, preferably about 70% to about 90% by weight carbon, and more preferably about 75% to about 80% by weight carbon, based upon the total solids in the composition taken as 100% by weight.

In one or more embodiments, the composition comprises less than about 0.5%, preferably less than about 0.1%, more preferably less than about 0.01%, and even more preferably about 0% by weight PFAS-containing surfactant, based upon the total weight of the composition taken as 100% by weight. In other embodiments, the composition comprises about 0.001% to about 2% by weight, preferably about 0.001% to about 1% by weight, and more preferably about 0.005% to about 1% by weight PFAS-containing surfactant, based upon the total weight of the composition taken as 100% by weight.

Regardless of the type of composition, it is preferred that the composition is substantially PFAS-free. In other words, preferred embodiments of the composition comprise less than about 2%, preferably less than about 1%, more preferably less than about 0.5%, and even more preferably about 0% by weight PFAS, based upon the total solids in the composition taken as 100% by weight. In some embodiments, the composition comprises less than about 0.01%, and preferably less than about 0.001%, by weight PFAS, based upon the total solids in the composition taken as 100% by weight.

### Methods of Using Compositions Including Star Macromolecule

The above-described compositions can be used to form various types of lithography underlayers, including antireflective coatings, carbon-rich layers, gap-fill layers, hardmask layers, planarizing layers, high- or low-refractive index material, and/or EUV assist or adhesion layers. The following generally describes some of these layer-forming processes, with the understanding that the previously described star macromolecules can be incorporated into any of these layers, as was also explained above with respect to the compositions.

Any microelectronic substrate can be utilized in the disclosed methods, but the substrate is preferably a semiconductor substrate, such as substrates formed from one or more of silicon, SiGe, SiO₂, Si₃N₄, SiON, aluminum, tungsten, tungsten silicide, gallium arsenide, germanium, tantalum, tantalum nitride, Ti₃N₄, hafnium, HfO₂, ruthenium, indium phosphide, tetramethyl silate and tetramethylcyclotetrasiloxane combinations (such as that sold under the name CORAL), SiCOH (such as that sold under the name Black Diamond, by SVM, Santa Clara, CA, US), or glass. Optional intermediate layers may be formed on the substrate prior to processing, with preferred intermediate layers being TiN or SiO₂ layers. The substrate can have a planar surface, or it can include topographic features (via holes, trenches, contact holes, raised features, lines, etc.). As used herein, “topography” refers to the height or depth of a structure in or on a substrate surface.

A layer of lithography underlayer composition is formed on the substrate or any intermediate layers (e.g., a primer layer). Regardless of the lithography underlayer composition utilized, the layer can be formed by any known application method, with one preferred method being spin-coating at speeds of about 1,000 rpm to about 2,000 rpm, and preferably about 1,250 rpm to about 1,750 rpm, for a time period of about 10 seconds to about 90 seconds, and preferably about 30 seconds to 60 seconds. Preferably, the lithography underlayer composition has good spin bowl compatibility, that is, it does not react or form a precipitate with common photoresist solvents such as PGME, PGMEA, ethyl lactate, cyclohexanone, or mixtures thereof.

After the lithography underlayer composition is applied, it is optionally heated to a temperature of about 140° C. to about 230° C., and more preferably about 185° C. to about 215° C., for about 15 seconds to about 90 seconds, and preferably about 30 seconds to about 60 seconds, to evaporate solvents.

As mentioned previously, the star macromolecule can be incorporated into the composition used to form any number of various lithography underlayers. Thus, the foregoing underlayer formation description is optionally repeated for any number of layers, depending on the particular application's needs. For example, carbon-rich layers (if included) tend to be a mid-level layer while hardmask layers (again, if included) tend to be in the upper half of the stack of layers, near the photoresist. In applications where both a carbon-rich layer and a hardmask layer are utilized, the hardmask layer tends to be applied to the carbon-rich layer. Assist layers and antireflective coatings (if included) tend to be applied at the upper portion of the stack, often immediately under the photoresist. Adhesion layers find application at any location where two different layers might have properties that are not conducive to adhering to one another (e.g., at the substrate). Gap-fill layers and planarizing layers are typically used once a high topographic region has been created, applied at sufficient levels to fill gaps between features in a pattern, and even to cover those features and form a planar layer on top of those features.

When used as an antireflective coating, the average thickness of the lithography underlayer after baking is typically about 5 nm to about 2.0 μm, and preferably about 75 nm to about 400 nm.

When used as a carbon-rich layer (such as a spin-on carbon layer), the average thickness of the lithography underlayer after baking is typically about 5 nm to about 2.0 μm, and preferably about 75 nm to about 400 nm. Additionally, the carbon-rich layer preferably comprises about 50% by weight or greater carbon, preferably about 50% by weight to about 99% by weight carbon, preferably about 70% to about 90% by weight carbon, and more preferably about 75% to about 80% by weight carbon, based upon the total weight of the layer taken as 100% by weight.

When used as a hardmask layer (e.g., such as the hardmask in a trilayer resist stack), the average thickness of the lithography underlayer after baking is typically about 5 nm to about 1 μm, and preferably about 20 nm to about 50 nm.

When used as gap-fill layer, the average thickness of the lithography underlayer after baking is typically about 5 nm to about 2.0 μm, and preferably about 75 nm to about 400 nm. When used as an assist layer or adhesion layer, the average thickness of the lithography underlayer after baking is typically about 5 nm to about 2,000 nm, and preferably about 75 nm to about 400 nm.

The average thickness is determined by taking the average of thickness measurements at twenty-five different locations of the lithography underlayer, with those thickness measurements being obtained using ellipsometry.

Regardless of the embodiment, any layer including the star macromolecule is preferably substantially PFAS-free. In other words, the formed layer preferably comprises less than about 2% by weight, preferably less than about 1% by weight, more preferably less than about 0.5% by weight, even more preferably less than about 0.05% by weight, and most preferably about 0% by weight PFAS, based upon the weight of that layer taken as 100% by weight.

A photoresist (i.e., imaging layer) can be applied to the lithography underlayer, or to any intermediate layer on the lithography underlayer, to form a photoresist layer. The photoresist layer can be formed by any conventional method, with one preferred method being spin coating the photoresist composition at speeds of about 350 rpm to about 4,000 rpm (preferably about 1,000 rpm to about 2,500 rpm) for a time period of about 10 seconds to about 60 seconds (preferably about 10 seconds to about 30 seconds). The photoresist layer is then optionally post-application baked (“PAB”) at a temperature of at least about 70° C., preferably about 80° C. to about 150° C., and more preferably about 100° C. to about 150° C., for time periods of about 30 seconds to about 120 seconds. The average thickness (determined as described previously) of the photoresist layer after baking is typically about 5 nm to about 120 nm, preferably about 10 nm to about 50 nm, and more preferably about 20 nm to about 40 nm.

The photoresist layer is subsequently patterned by exposure to radiation for a dose of about 10 mJ/cm² to about 200 mJ/cm², preferably about 15 mJ/cm² to about 100 mJ/cm², and more preferably about 20 mJ/cm² to about 50 mJ/cm² at a variety of wavelengths, but preferably about 193 nm or about 13.5 nm (i.e., EUV exposure). More specifically the photoresist layer is exposed using a mask positioned above the surface of the photoresist layer. The mask has areas designed to permit the radiation to reflect from or pass through the mask and contact the surface of the photoresist layer. The remaining portions of the mask are designed to absorb the light to prevent the radiation from contacting the surface of the photoresist layer in certain areas. Those skilled in the art will readily understand that the arrangement of reflecting and absorbing portions is designed based upon the desired pattern to be formed in the photoresist layer and ultimately in the substrate or any intermediate layers.

After exposure, the photoresist layer is preferably subjected to a post-exposure bake (“PEB”) at a temperature of less than about 180° C., preferably about 60° C. to about 140° C., and more preferably about 80° C. to about 130° C., for a time period of about 30 seconds to about 120 seconds (preferably about 30 seconds to about 90 seconds).

The photoresist layer is then dry etched or (wet) developed to form the pattern. Depending upon whether the photoresist used is positive-working or negative-working, the developer either removes the exposed portions of the photoresist layer or removes the unexposed portions of the photoresist layer to form the pattern. The pattern is then transferred through the various layers, and finally to the substrate. This pattern transfer can take place via plasma etching (e.g., CF₄ etchant, O₂ etchant) or a wet etching or developing process.

It will be appreciated that the star macromolecules ability to perform many or all of the functions of a surfactant provides a number of advantages and shows superior performance over standard random polymers or block copolymers. For example, the inventive star macromolecules minimize film thickness non-uniformities while being PFAS- and/or silicon-free, an important parameter for films that will undergo an etch transfer process. Additionally, the use of RAFT polymerization to synthesize the arms of the star molecule allows for tailored design of both monomer composition and number of repeat units. In general, a lower number of repeat units tends to increase compatibility with the film and reduce phase separation. Furthermore, monomer selection can be utilized to allow the star molecule to move to the top surface of the film or layer during the spin coating process.

In some embodiments, layers formed using the star macromolecules described herein will have little to no striations. The amplitude or mean depth of the striations is a function of the film thickness. “Mean depth” is determined as described in Example 11. Preferably, these layers will have a % periodical variation in thickness (amplitude of striation divided by total film thickness) of about 5% or lower, more preferably about 2% or lower, and even more preferably about 1% or lower.

Additional advantages of the various embodiments will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present disclosure encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the disclosure. It is to be understood, however, that these examples are provided by way of illustration, and nothing therein should be taken as a limitation upon the overall scope.

### Example 1

### Grafting of 4-Cyano-4-(((dodecylthio)carbonothioyl)thio)pentanoic Acid to TEPIC

To a 100-mL round bottom flask (RBF) were added 0.223 gram of ethyltriphenylphosphonium bromide (ETPPB, TCI Chemicals, Portland, OR), 12.11 grams of 4-cyano-4-(((dodecylthio)carbonothioyl)thio)pentanoic acid (Boron Molecular, Raleigh, NC), 2.97 grams of triglycidyl isocyanurate (TEPIC, TCI Chemicals, Portland, OR), and 22.96 grams of propylene glycol methyl ether acetate (PGMEA; Fujifilm Ultrapure Solutions, Carrolton, TX). The reaction was heated under a blanket of N₂ at 110° C. for 24 hours before being cooled to room temperature and collected as TEPIC-g-CTA mother liquor. The reaction that took place is shown in Scheme A.

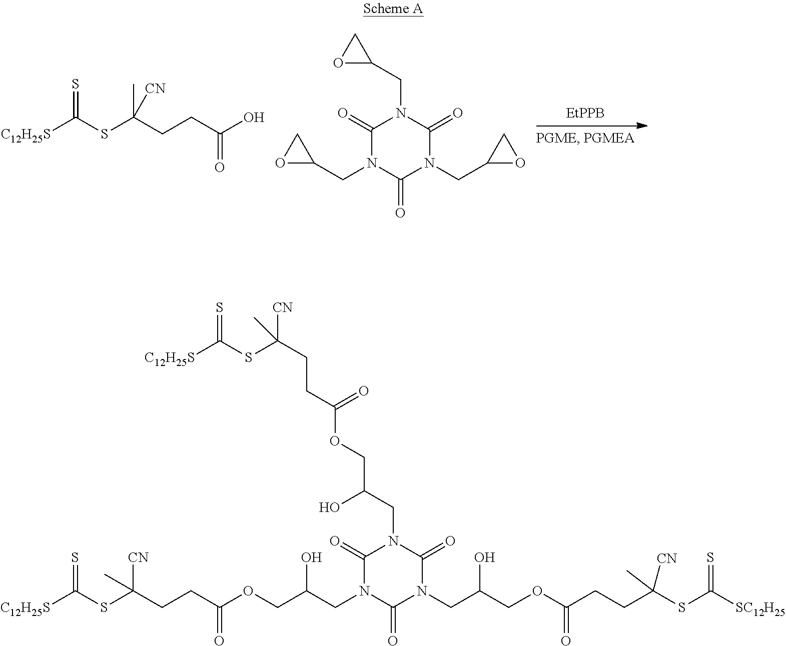

### Example 2

### Polymerization of Isobornyl Methacrylate on TEPIC-g-CTA

To a 100-mL RBF were added 10 grams of isobornyl methacrylate (TCI Chemicals, Portland, OR), 3.77 grams of TEPIC-g-CTA mother liquor from Example 1, 0.041 gram of azobisisobutyronitrile (AIBN; available from Charkit, Norwalk, CT), and 13.45 grams of PGMEA (Fujifilm Ultrapure Solutions, Carrolton, TX). The reaction was sparged with N₂ for 10 minutes before being heated at 70° C. for 24 hours. The reaction was then cooled to room temperature and collected as mother liquor. The reaction that took place is shown in Scheme B.

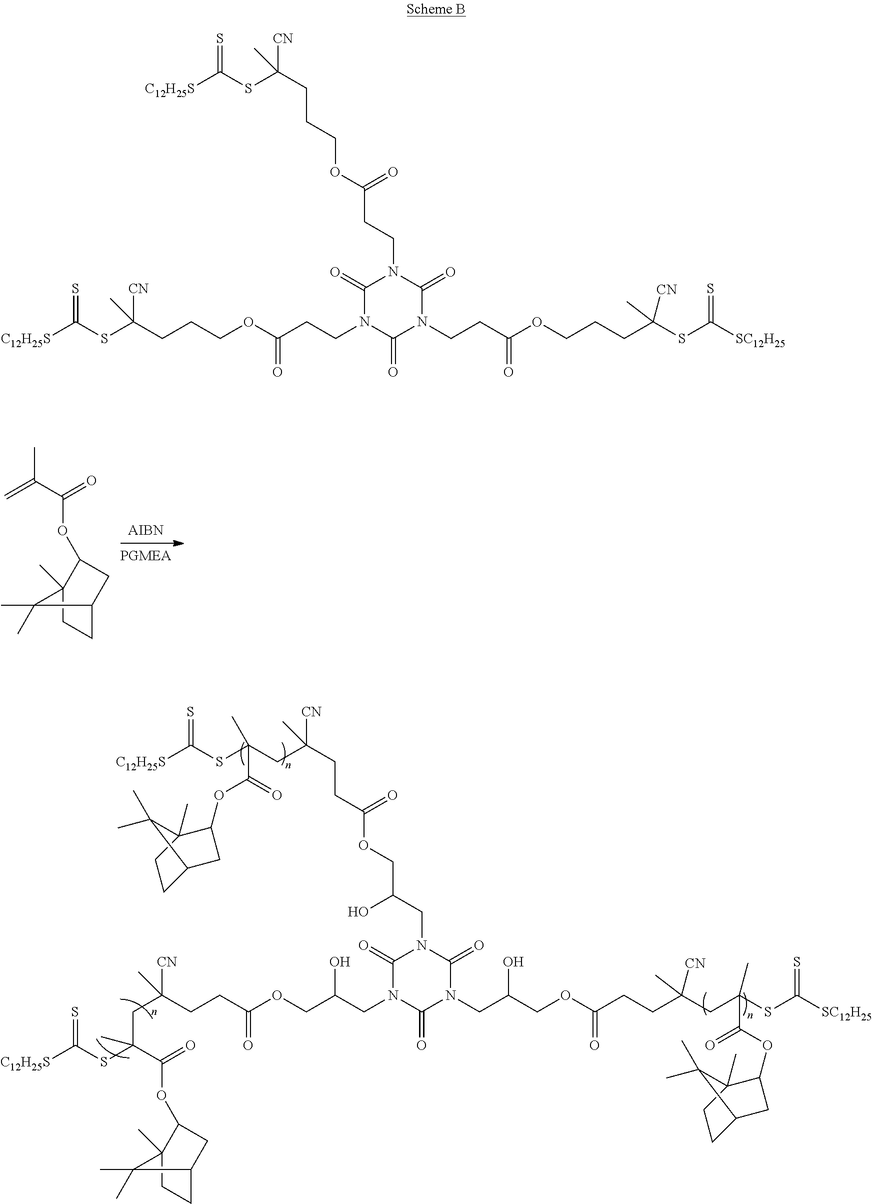

### Example 3

### Polymerization of Dicyclopentanyl Methacrylate on TEPIC-g-CTA

To a 100-mL RBF were added 9.91 grams of dicyclopentanyl methacrylate (TCI Chemicals, Portland, OR), 3.77 grams of TEPIC-g-CTA mother liquor from Example 1, 0.041 gram of AIBN (Charkit, Norwalk, CT), and 14.93 grams of PGMEA (Fujifilm Ultrapure Solutions, Carrolton, TX). The reaction was sparged with N₂ for 10 minutes before being heated at 70° C. for 24 hours. The reaction was then cooled to room temperature and collected as mother liquor. The reaction that took place is shown in Scheme C.

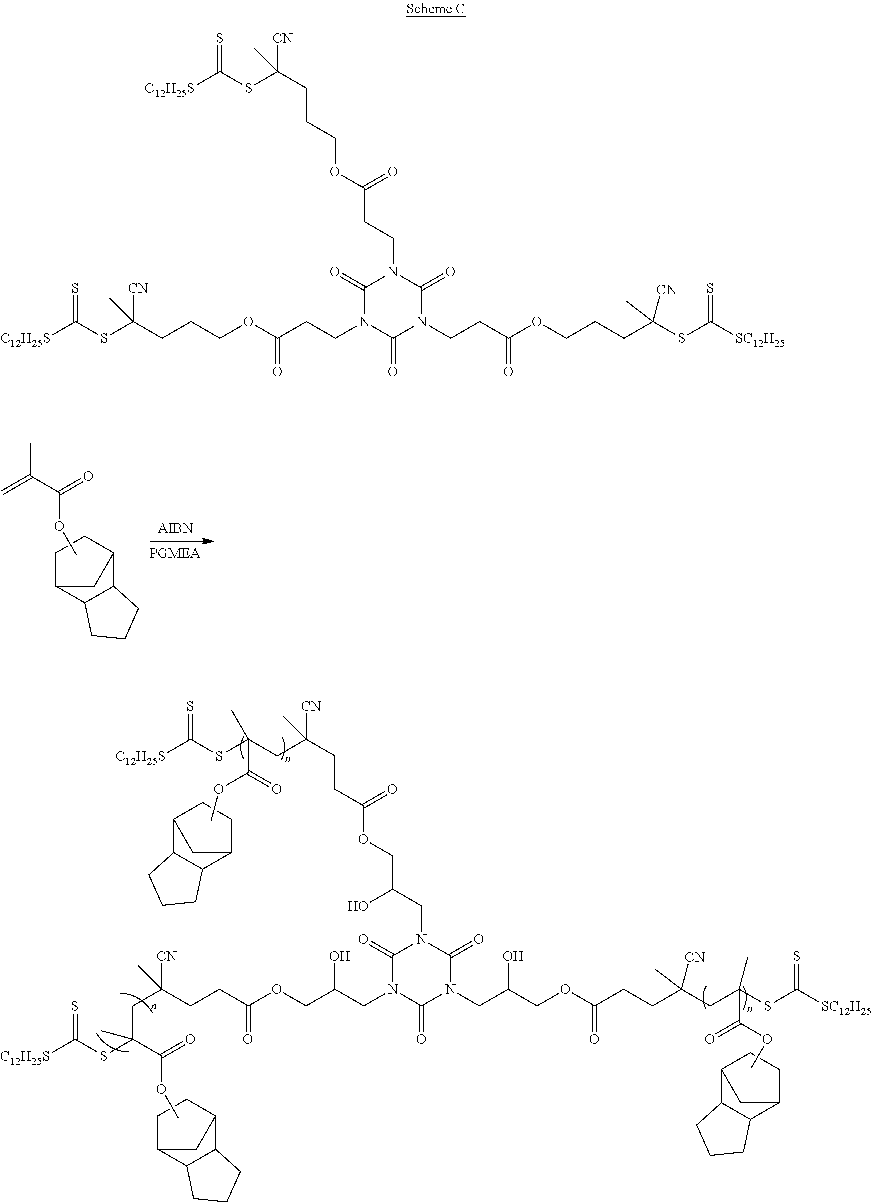

### Example 4

### Lower-Mw Isobomyl Methacrylate

To a 100-mL RBF were added 10.00 grams of isobornyl methacrylate (TCI Chemicals, Portland, OR), 8.48 grams of TEPIC-g-CTA mother liquor from Example 1, 0.041 gram of AIBN (Charkit, Norwalk, CT), and 15.15 grams of PGMEA (Fujifilm Ultrapure Solutions, Carrolton, TX). The reaction was sparged with N₂ for 10 minutes before being heated at 70° C. for 24 hours. The reaction was then cooled to room temperature and collected as mother liquor. The reaction in this Example was the same as Scheme B above.

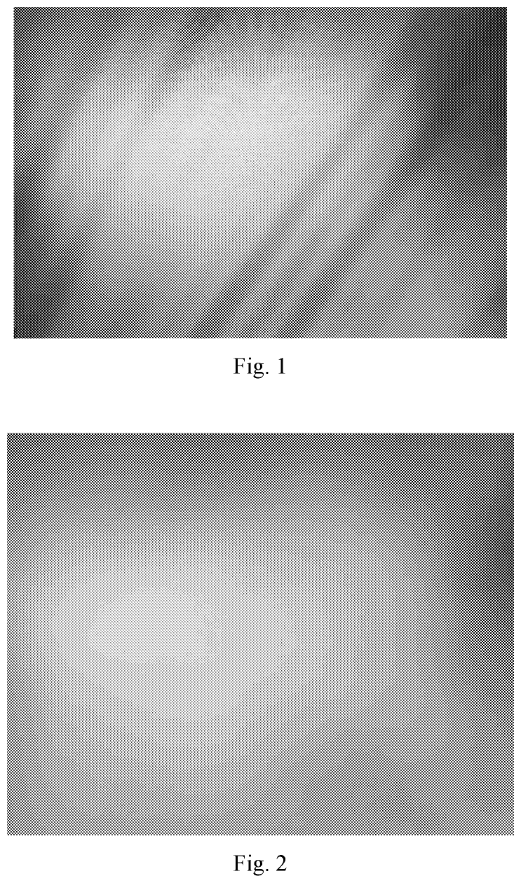

The synthesized product (i.e., surfactant) was then utilized at a 0.1% by weight loading in a formulation containing 23% by weight epoxy cresol novolac (EPOKUKDO YDCN-500-90P; available from Kukdo Chemical), 1% by weight relative to polymer solids (a thermal acid generator or “TAG” sold under the name K-PURE TAG2689 by King Industries), and 76.8% by weight 80%/20% PGMEA/PGME. This surfactant-containing formulation was compared to a control that did not contain the surfactant. Each formulation was deposited on respective silicon wafers by spin coating at 1,500 rpm and baking at 205° C. for 60 seconds to form films that were about 1 μm thick. The presence of striations in the films was assessed using an optical microscope (500×). Alternating bands of different colors indicate a periodic change in film thickness for the surfactant-free control, as shown in FIG. 1. As shown in FIG. 2, the inclusion of the surfactant in the formulation significantly reduced or even eliminated the striations.

### Example 5

### Random Copolymer of Pentafluorostyrene and Isobornyl Methacrylate on TEPIC-g-CTA

To a 100-mL RBF were added 2.91 grams of pentafluorostyrene (TCI Chemicals, Portland, OR), 3.33 grams of isobornyl methacrylate (TCI Chemicals, Portland, OR), 5.65 grams of TEPIC-g-CTA mother liquor from Example 1, 0.041 gram of AIBN (Charkit, Norwalk, CT), and 9.46 grams of PGMEA (Fujifilm Ultrapure Solutions, Carrolton, TX). The reaction was sparged with N₂ for 10 minutes before being heated at 70° C. for 24 hours. The reaction was then cooled to room temperature and collected as mother liquor. The reaction that took place is shown in Scheme D.

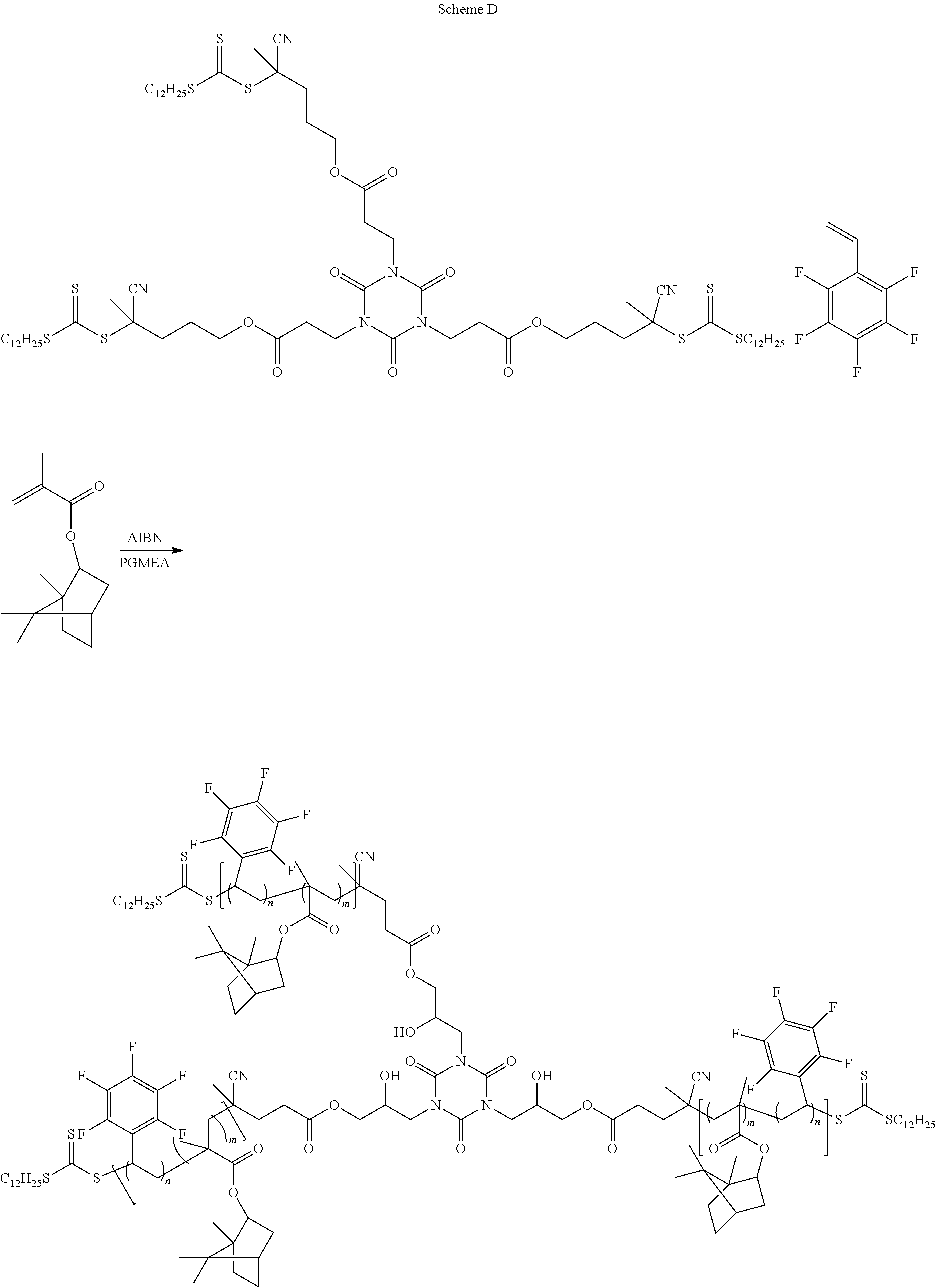

### Example 6

### Polymerization of 2-(Ethoxyethoxy)Ethyl Acrylate on TEPIC-g-CTA

To a 100-mL RBF were added 5.65 grams of 2-(ethoxyethoxy)ethyl acrylate (TCI Chemicals, Portland, OR), 9.43 grams of TEPIC-g-CTA mother liquor from Example 1, 0.103 gram of AIBN (Charkit, Norwalk, CT), and 8.62 grams of PGMEA (Fujifilm Ultrapure Solutions, Carrolton, TX). The reaction was sparged with N₂ for 10 minutes before being heated at 60° C. for 24 hours. The reaction was then cooled to room temperature and collected as TEPIC-g-P(EtO) mother liquor. The reaction that took place is shown in Scheme E.

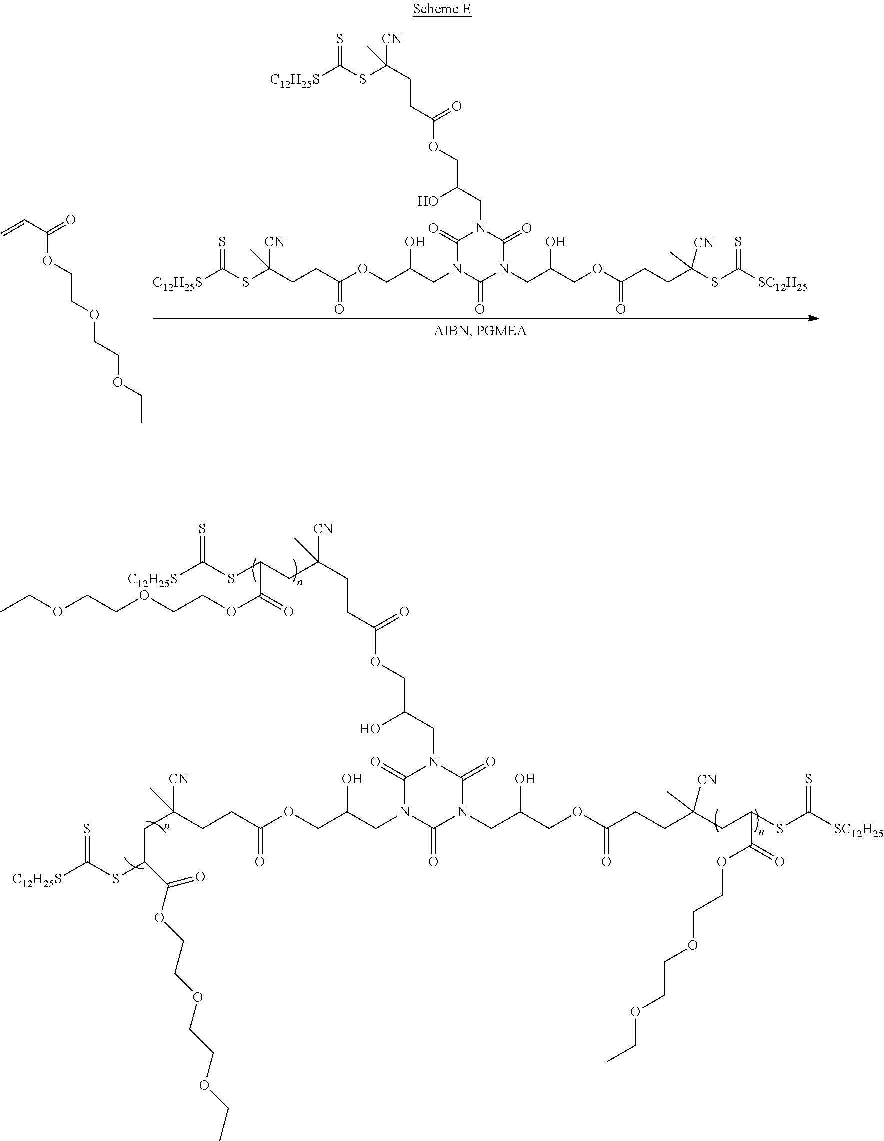

### Example 7

### Polymerization of Pentafluorostyrene on Macromolecule of Example 6

To a 100-mL RBF were added 2.91 grams of pentafluorostyrene (TCI Chemicals, Portland, OR), 5.89 grams of TEPIC-g-P(EtO) mother liquor from Example 6, 0.026 gram of AIBN (Charkit, Norwalk, CT), and 4.41 grams of PGMEA (Fujifilm Ultrapure Solutions, Carrolton, TX). The reaction was sparged with N₂ for 10 minutes before being heated at 70° C. for 24 hours. The reaction was then cooled to room temperature and collected as mother liquor. The reaction that took place is shown in Scheme F.

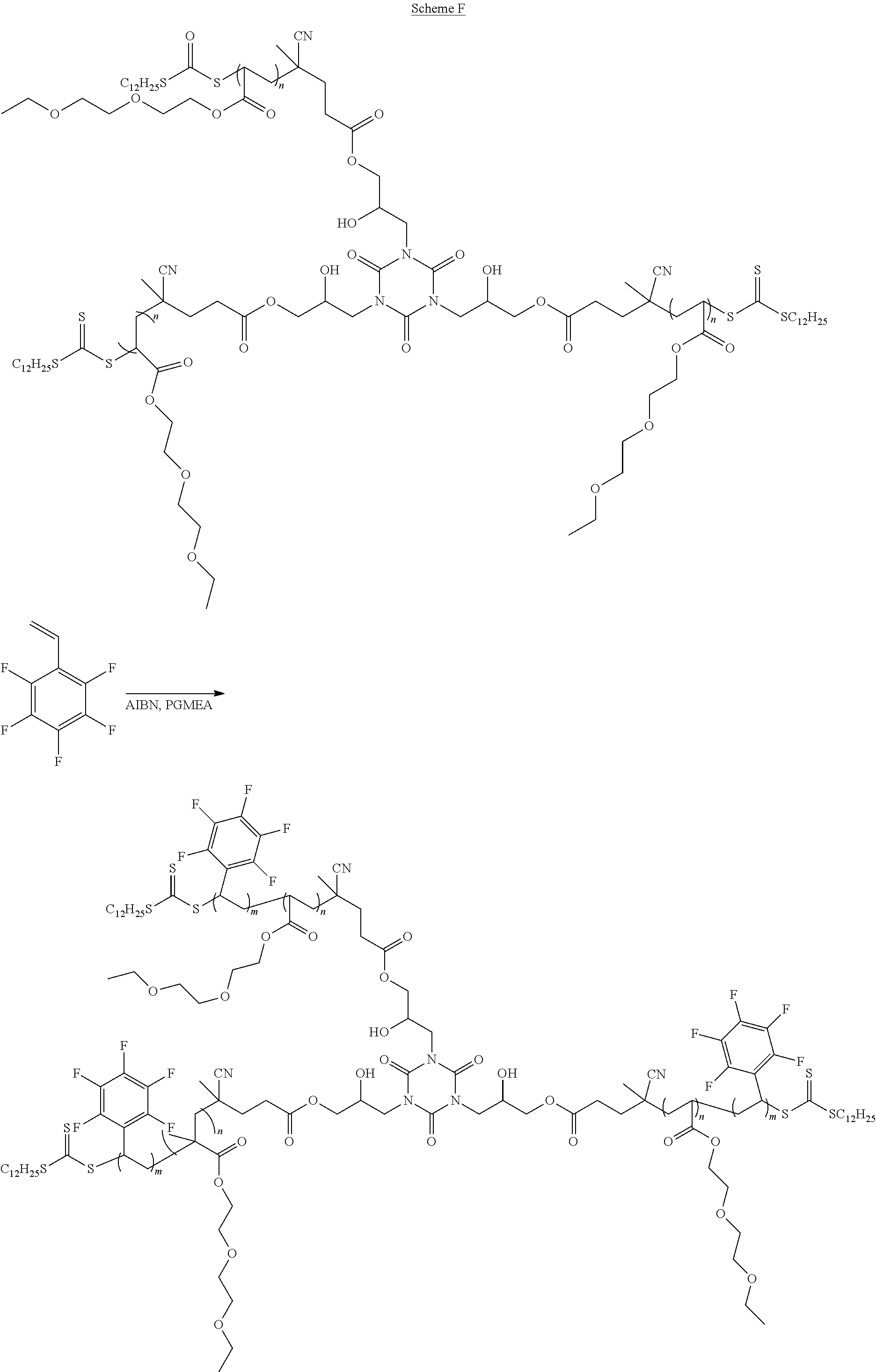

### Example 8

### Grafting of RAFT CTA to MA-DGIC

To a 100-mL round bottom flask were added 0.111 gram of ETPPB (TCI Chemicals, Portland, OR), 12.11 grams of 4-cyano-4-(((dodecylthio)carbonothioyl)thio)pentanoic acid (Boron Molecular, Raleigh, NC), 4.22 grams of monoallyl diglycidylisocyanurate (MA-DGIC) (Nissan Chemical Corporation, Toyama, Japan), 12.33 grams of PGMEA (Fujifilm Ultrapure Solutions, Carrolton, TX) and 12.33 grams of PGME (Fujifilm Ultrapure Solutions, Carrolton, TX). The reaction was heated under a blanket of N₂ at 90° C. for 24 hours before being cooled to room temperature and collected as MA-DGIC-g-CTA mother liquor. The reaction that took place is shown in Scheme G.

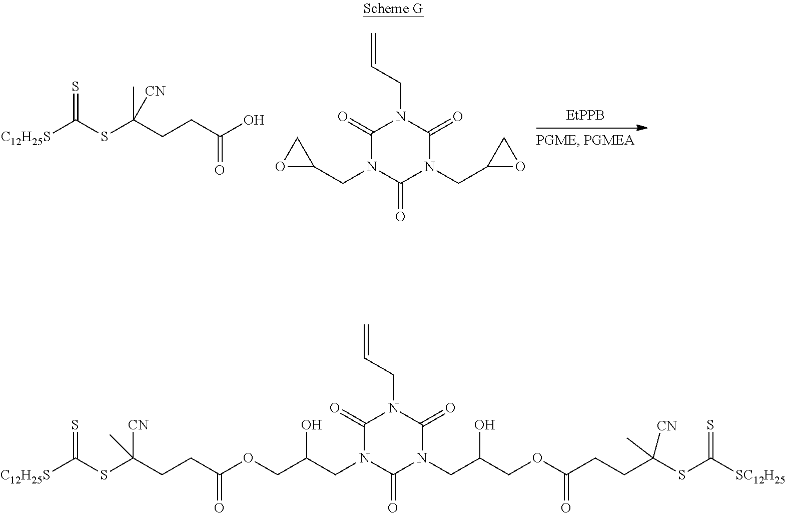

### Example 9

### Polymerization of Isobornyl Methacrylate on MA-DGIC-g-CTA

To a 100-mL RBF were added 10 grams of isobornyl methacrylate (TCI Chemicals, Portland, OR), 2.72 grams of MA-DGIC-g-CTA mother liquor from Example 8, 0.041 gram of AIBN (Charkit, Norwalk, CT), and 15.07 grams of PGMEA (Fujifilm Ultrapure Solutions, Carrolton, TX). The reaction was sparged with N₂ for 10 minutes before being heated at 70° C. for 24 hours. The reaction was then cooled to room temperature and collected as mother liquor. The reaction that took place is shown in Scheme H.

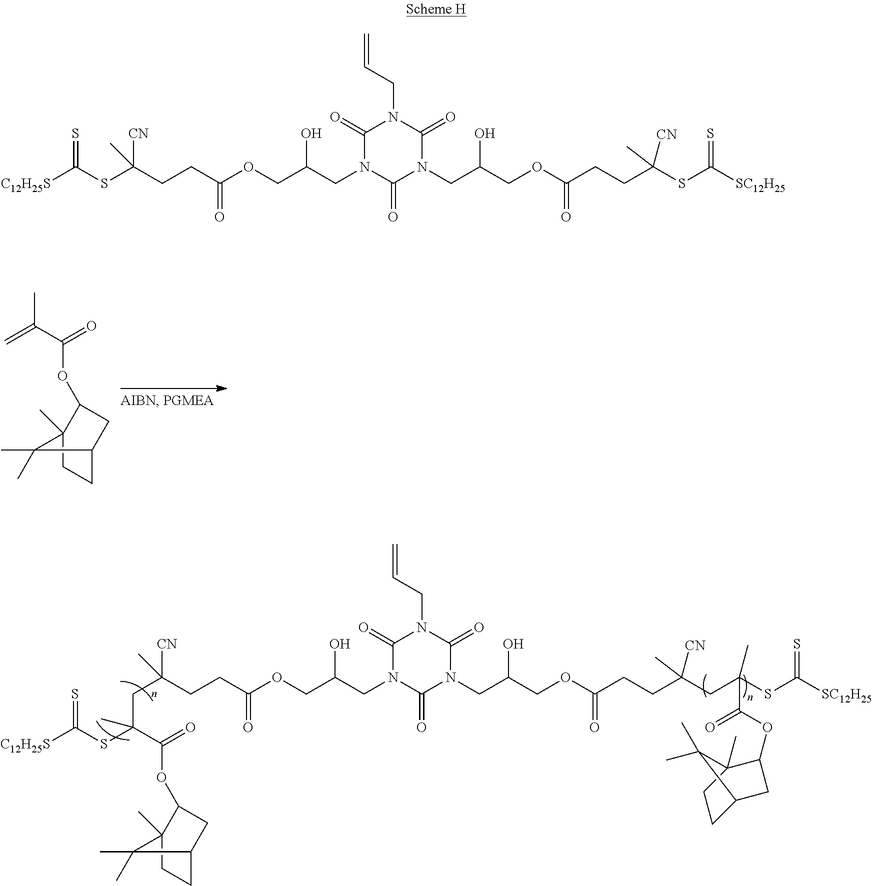

### Example 10

### Characterization and Testing of Surfactants

The respective molecular weights of each surfactant were determined by gel permeation chromatography (GPC) using 40° C. THF flowing at 1 mL/min and calibrated with linear PS standards.

Surfactants were each tested in the following formulation: 2.3 grams of epoxy cresol novolac (Kukdo Chemical Co., Ltd., Seoul, Korea), 0.23 gram of K-PURE® TAG2689 (10% w/w solution in PGME, King Industries, Norwalk, CT), 0.23 gram of each surfactant (1% w/w solution in PGMEA), 1.34 grams of PGME (Fujifilm Ultrapure Solutions, Carrolton, TX), and 5.93 grams of PGMEA (Fujifilm Ultrapure Solutions, Carrolton, TX). The formulation was mixed until homogeneous (~2 hours) followed by filtering using a 0.1-μm end-point filter. The formulation was then deposited on a 100-mm Si wafer by spin coating at 1,500 rpm and baked at 205° C. for 60 seconds. After baking, the film was examined by optical microscope for the presence of striations.

Table 1 shows the molecular weight and coat quality of the surfactants synthesized in Examples 2-5.

TABLE 1
Molecular Weight and Coat Quality

| Surfactant | Mw (kDa) | Striations |
|---|---|---|
| Control - no surfactant | N/A | Yes |
| Example 2 | 7.4 | Minor |
| Example 3 | 7.6 | Minor |
| Example 4 | 4.5 | Not visible |
| Example 5 | 4.7 | Not visible |

### Example 11

### Characterization, Optimization, and Testing of Surfactants

A series of surfactants were synthesized and tested with an exemplary spin-on carbon material. Surfactants were prepared as described above, varying the amount and type of hydrophilic and hydrophobic monomer. The synthesized surfactants were then utilized at 0.1% loading in a formulation containing 23% by weight YDCN-500-90P epoxy cresol novolac, 1% TAG, and the remainder 80%/20% PGMEA/PGME. The TAGs used were K-PURE® CXC-1821 (quaternary ammonium blocked super acid catalyst) and K-PURE® TAG-2689 (quaternary ammonium blocked triflic acid thermal acid generator), both from King Industries.

Table 1 shows the composition of the various surfactants, where pentafluorostyrene is abbreviated as “PFS,” 4-tert-butylstyrene as “tBS,” and 2-(ethoxyethoxy)ethyl acrylate as “EtO.” The number before the monomer abbreviation refers to the total molar ratio of monomer to TEPIC-g-RAFT, where dividing the number by 3 gives the number of theoretical repeat units per “arm” of the surfactant. The reaction conditions used in Examples 6 and 7 were used, along with similar conditions for 4-tert-butylstyrene by changing the reaction temperature to 110° C.

Each formulation was deposited on a Si wafer by spin coating at 1,500 rpm and baking at 205° C. for 60 seconds. Further assessment of the film coating quality was done by using the KLA Tencor P-7 stylus profiler which measures the surface roughness (peaks and valleys). The oscillations/striations tend to have a periodicity of ~100 μm, so a scan length of 1 mm was used to capture an average of striation height. This is indicated in the ensuing tables by the term “mean depth” while an average roughness value is given by Rq. Formulations with a hydrophilic first block and a large amount of PFS (at least 24 PFS) yielded completely flat films.

TABLE 2
Series of Surfactant-Containing Material Formulations

| Sample | | | Mean Depth | | |
|---|---|---|---|---|---|
| Number | 1^{st} block | 2^{nd} block | (nm) | Rq | Catalyst |
| 1 | 9 PFS | 9 EtO | ~75 | 25.2 | CXC-1821 |
| 2 | 9 PFS | 9 EtO | ~2.5-3 | 2.16 | TAG-2689 |
| 3 | 18 EtO | 18 PFS | ~40 | 38.1 | CXC-1821 |
| 4 | 18 EtO | 18 PFS | ~2.5-3 | 1.99 | TAG-2689 |
| 5 | 9 PFS | 18 EtO | ~65 | 24.0 | CXC-1821 |
| 6 | 9 PFS | 18 EtO | ~3-3.5 | 1.90 | TAG-2689 |
| 7 | 15 EtO | 18 tBS | ~55 | 17.9 | CXC-1821 |
| 8 | 15 EtO | 18 tBS | ~7-12 | 3.75 | TAG-2689 |
| 9 | 9 PFS | 30 EtO | ~50 | 21.8 | CXC-1821 |
| 10 | 9 PFS | 30 EtO | ~5-6 | 2.28 | TAG-2689 |
| 11 | 18 PFS | 18 EtO | ~60 | 22.1 | CXC-1821 |
| 12 | 18 PFS | 18 EtO | ~5.5-6 | 3.18 | TAG-2689 |
| 13 | 18 tBS | 18 EtO | ~90 | 37.3 | CXC-1821 |
| 14 | 18 tBS | 18 EtO | ~2 | 1.26 | TAG-2689 |
| 15 | 9 tBS | 9 EtO | ~40 | 15.6 | CXC-1821 |
| 16 | 9 tBS | 9 EtO | ~3.5-4 | 1.88 | TAG-2689 |
| 17 | 9 tBS | 18 EtO | ~35 | 16.8 | CXC-1821 |
| 18 | 9 tBS | 18 EtO | ~5 | 6.96 | TAG-2689 |
| 19 | 9 EtO | 18 tBS | ~30 | 13.7 | CXC-1821 |
| 20 | 9 EtO | 18 tBS | ~5-10 | 3.76 | TAG-2689 |
| 21 | 18 PFS | 9 EtO | ~45 | 18.1 | CXC-1821 |
| 22 | 18 PFS | 9 EtO | ~2-3 | 1.76 | TAG-2689 |
| 23 | 18 PFS | 30 EtO | ~70 | 22.8 | CXC-1821 |
| 24 | 12 PFS | 24 EtO | ~60 | 17.9 | CXC-1821 |
| 25 | 12 PFS | 12 EtO | ~60 | 24.7 | CXC-1821 |
| 26 | 9 tBS | 12 EtO | ~35 | 14.3 | CXC-1821 |
| 27 | 12 PFS | 18 EtO | ~130 | 47.6 | CXC-1821 |
| 28 | 18 tBS | 30 EtO | ~25 | 9.75 | CXC-1821 |
| 29 | 24 tBS | 18 EtO | ~15 | 5.63 | CXC-1821 |
| 30 | 24 tBS | 30 EtO | ~12 | 5.64 | CXC-1821 |
| 31 | 18 EtO | 24 PFS | ~1-2 | 1.84 | CXC-1821 |
| 32 | 18 EtO | 30 PFS | ~1-2 | 1.24 | CXC-1821 |
| 33 | 30 tBS | 18 EtO | ~20 | 10.7 | CXC-1821 |
| 34 | 18 EtO | 18 PFS | ~15 | 5.86 | CXC-1821 |
| 35 | 18 EtO | 18 tBS | ~20 | 8.84 | CXC-1821 |
| 36 | 30 tBS | 30 EtO | ~20 | 8.93 | CXC-1821 |
| 37 | 18 EtO | 30 tBS | ~50 | 17.4 | CXC-1821 |
| 38 | 12 EtO | 24 PFS | ~1-2 | 2.12 | CXC-1821 |
| 39 | 18 EtO | 39 PFS | ~1-2 | 1.20 | CXC-1821 |

1. A method of forming a structure, said method comprising applying a composition on a surface of a substrate, or on one or more intermediate layers optionally present on said surface of said substrate, to form a layer of that composition, said composition comprising a star macromolecule dispersed or dissolved in a solvent system, wherein:
said star macromolecule comprises a central core and at least two arms radiating from said central core, said at least two arms each comprising at least two recurring monomers that are different from said central core;
said central core is hydrophobic or hydrophilic and
if said central core is hydrophobic, said at least two recurring monomers are hydrophilic; and
if said central core is hydrophilic, said at least two recurring monomers are hydrophobic; and
at least one of (I), (II), (III), (IV), or (V) is true:
(I) said layer comprises about 50% by weight to about 99% by weight carbon, and further comprising:
forming a hardmask layer on said layer;
optionally forming one or more additional intermediate layers on said hardmask layer; and
forming a photoresist layer on said one or more additional intermediate layers on said hardmask layer, if present, or on said hardmask layer if no additional intermediate layer is present;
(II) one or more intermediate layers are present and include an uppermost intermediate layer that comprises a carbon-rich layer that comprises about 50% by weight to about 99% by weight carbon, and further comprising:
optionally forming one or more additional intermediate layers on said layer; and
forming a photoresist layer on said one or more additional intermediate layers on said layer, if present, or on said layer if no additional intermediate layer is present;
(III) further comprising:
(b) (i) forming a carbon-rich layer that comprises about 50% by weight to about 99% by weight carbon on said layer;
(ii) optionally forming one or more additional intermediate layers on said carbon-rich layer; and
(iii) forming a photoresist layer on said one or more additional intermediate layers on said carbon-rich layer, if present, or on said carbon-rich layer if no additional intermediate layer is present;
(b) (i) forming a hardmask layer on said layer;
(ii) optionally forming one or more additional intermediate layers on said hardmask layer; and
(iii) forming a photoresist layer on said one or more additional intermediate layers on said hardmask layer, if present, or on said hardmask layer if no additional intermediate layer is present; or
(c) (i) forming a carbon-rich layer that comprises about 50% by weight to about 99% by weight carbon on said layer;
(ii) forming a hardmask layer on said carbon-rich layer;
(iii) optionally forming one or more additional intermediate layers on said hardmask layer; and
(iv) forming a photoresist layer on said one or more additional intermediate layers on said hardmask layer, if present, or on said hardmask layer if no additional intermediate layer is present;
(IV) said surface of said substrate comprises a pattern comprising a plurality of gaps, and said applying a composition comprises depositing said composition in at least some of said gaps; or
(V) said one or more intermediate layers are present and include one or both of a carbon-rich layer that comprises about 50% by weight to about 99% by weight carbon or a hardmask layer, and further comprising forming a photoresist layer on said layer.

2. The method of claim 1, wherein said at least two arms comprise two to about 30 recurring monomers per arm, and the number and type of recurring monomers on each arm can be the same or different.

3. The method of claim 2, wherein said star macromolecule comprises at least three arms radiating from said central core.

4. The method of claim 1, wherein said central core is hydrophilic and said at least two recurring monomers are hydrophobic.

5. The method of claim 1, wherein said at least two arms comprise at least one hydrophobic monomer and at least one hydrophilic monomer.

6. The method of claim 1, wherein said at least two arms comprise a block copolymer.

7. The method of claim 6, wherein one block of said block copolymer is hydrophobic, and another block of said block copolymer is hydrophilic.

8. The method of claim 1 wherein said central core comprises an isocyanurate moiety, a double-branched chain alkane moiety, a multifunctional polyether moiety, or combinations thereof.

9. The method of claim 1 wherein:
said at least two recurring monomers that are hydrophobic are chosen from pentafluorostyrene, isobornyl methacrylate, dicyclopentanyl methacrylate, tert-butylstyrene, methylstyrene, fluorostyrene, 3,5-difluorostyrene, or combinations thereof; and
said at least two recurring monomers that are hydrophilic are chosen from 2-(ethoxyethoxy)ethyl acrylate, 2-methoxyacrylate, methyl acrylate, 2-(ethoxyethoxy)methyl acrylate, 2-methoxymethacrylate, methyl methacrylate, or combinations thereof.

10. The method of claim 1, wherein said star macromolecule is present in said composition at a level of about 0.001% by weight to about 1% by weight, based on the total solids in the composition taken as 100% by weight.

11. The method of claim 1, wherein said star macromolecule is chosen from one or more of

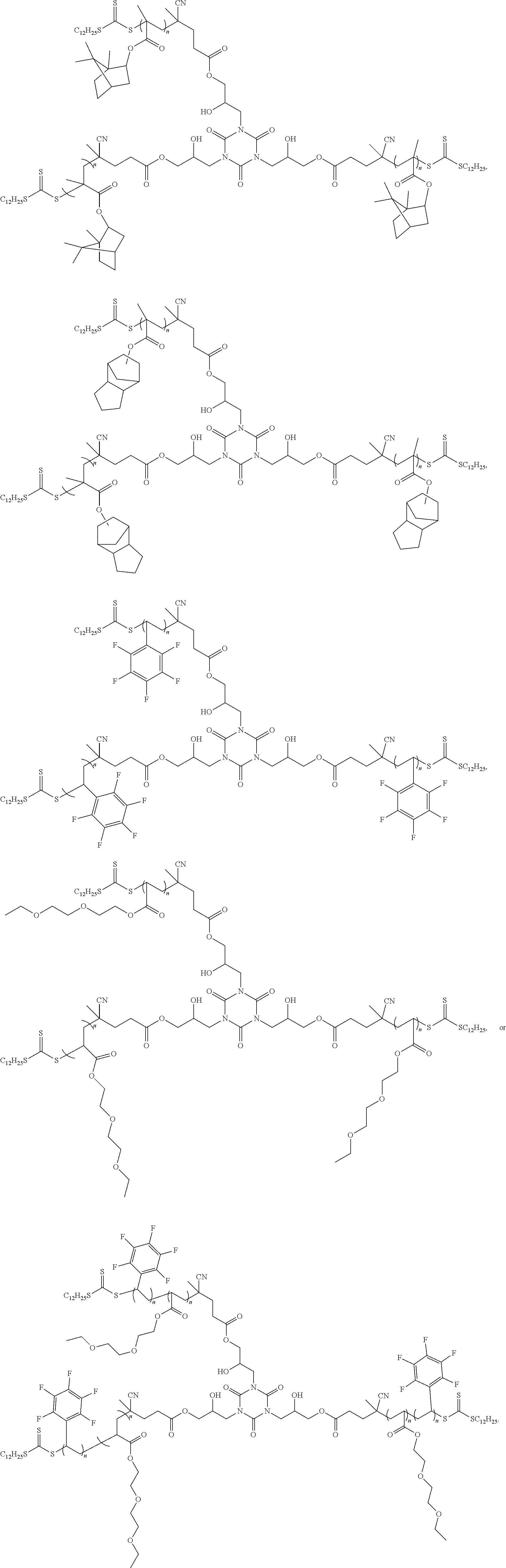

12. The method of claim 1, further comprising:
exposing said photoresist layer to radiation so as to form a pattern in said photoresist layer; and
transferring said pattern to said substrate.

13. The method of claim 1, wherein said gaps of (IV) are formed from topographic features, and said composition is applied at a sufficient thickness to cover said topographic features and form a planarizing layer of said layer on said topographic features.

14. The method of claim 1, wherein at least one of the following is true:
said star macromolecule is PFAS-free;
said star macromolecule does not include any fluorine atoms;
said star macromolecule does not include any silicon atoms;
said star macromolecule does not include a metal phthalocyanine or moiety thereof; or
said star macromolecule does not include any iodine atoms.

15. A microelectronic structure comprising:
a substrate having a surface, there being one or more intermediate layers optionally present on said surface of said substrate;
a layer on said surface of said substrate, or on said one or more intermediate layers if present, said layer comprising a star macromolecule that comprises a central core and at least two arms radiating from said central core, said at least two arms each comprising at least two recurring monomers that are different from said central core, wherein:
said central core is hydrophobic or hydrophilic;
if said central core is hydrophobic, said at least two recurring monomers are hydrophilic; and
if said central core is hydrophilic, said at least two recurring monomers are hydrophobic; and
at least one of (I), (II), (III), (IV), or (V) is true:
(I) said layer comprises about 50% by weight to about 99% by weight carbon;
a hardmask layer is on said layer;
one or more additional intermediate layers are optionally on said hardmask layer; and
a photoresist layer is on said one or more additional intermediate layers on said hardmask layer, if present, or on said hardmask layer if no additional intermediate layer is present;
(II) one or more intermediate layers are present on said surface of said substrate and include an uppermost intermediate layer that comprises a carbon-rich layer comprising about 50% by weight to about 99% by weight carbon;
optionally one or more additional intermediate layers on said layer; and
a photoresist layer on said one or more additional intermediate layers on said layer, if present, or on said layer if no additional intermediate layer is present;
(III) further comprising:
(b) (i) a carbon-rich layer that comprises about 50% by weight to about 99% by weight carbon is on said layer;
(ii) one or more additional intermediate layers are optionally on said carbon-rich layer; and
(iii) a photoresist layer is on said one or more additional intermediate layers on said carbon-rich layer, if present, or on said carbon-rich layer if no additional intermediate layer is present;
(b) (i) a hardmask layer on said layer;
(ii) one or more additional intermediate layers are optionally on said hardmask layer; and
(iii) a photoresist layer is on said one or more additional intermediate layers on said hardmask layer, if present, or on said hardmask layer if no additional intermediate layer is present; or
(c) (i) a carbon-rich layer that comprises about 50% by weight to about 99% by weight carbon on said layer;
(ii) a hardmask layer on said carbon-rich layer;
(iii) one or more additional intermediate layers on said hardmask layer; and
(iv) a photoresist layer on said one or more additional intermediate layers on said hardmask layer, if present, or on said hardmask layer if no additional intermediate layer is present;
(IV) said surface of said substrate comprises a pattern comprising a plurality of gaps, and said layer is present in at least some of said gaps; or
(V) said one or more intermediate layers are present on said surface of said substrate and include one or both of a carbon-rich layer that comprises about 50% by weight to about 99% by weight carbon or a hardmask layer, and further comprising forming a photoresist layer on said layer.

16. The microelectronic structure of claim 15, wherein said at least two arms comprise two to about 30 recurring monomers per arm, and the number and type of recurring monomers on each arm can be the same or different.

17. The microelectronic structure of claim 15, wherein said star macromolecule comprises at least three arms radiating from said central core.

18. The microelectronic structure of claim 15, wherein said central core is hydrophilic and said at least two recurring monomers are hydrophobic.

19. The microelectronic structure of claim 15, wherein said at least two arms comprise at least one hydrophobic monomer and at least one hydrophilic monomer.

20. The microelectronic structure of claim 15, wherein said at least two arms comprise a block copolymer.

21. The microelectronic structure of claim 20, wherein one block of said block copolymer is hydrophobic, and the other block of said block copolymer is hydrophilic.

22. The microelectronic structure of claim 15, wherein said central core comprises an isocyanurate moiety, a double-branched chain alkane moiety, a multifunctional polyether moiety, or combinations thereof.

23. The microelectronic structure of claim 15, wherein:
said at least two recurring monomers that are hydrophobic are chosen from pentafluorostyrene, isobornyl methacrylate, dicyclopentanyl methacrylate, tert-butylstyrene, methylstyrene, fluorostyrene, 3,5-difluorostyrene, or combinations thereof; and
said at least two recurring monomers that are hydrophilic are chosen from 2-(ethoxyethoxy)ethyl acrylate, 2-methoxyacrylate, methyl acrylate, 2-(ethoxyethoxy)methyl acrylate, 2-methoxymethacrylate, methyl methacrylate, or combinations thereof.

24. The microelectronic structure of claim 15, wherein said star macromolecule is present in said layer at a level of about 0.001% by weight to about 1% by weight, based on the total weight of the layer taken as 100% by weight.

25. The microelectronic structure of claim 15, wherein said star macromolecule is chosen from one or more of

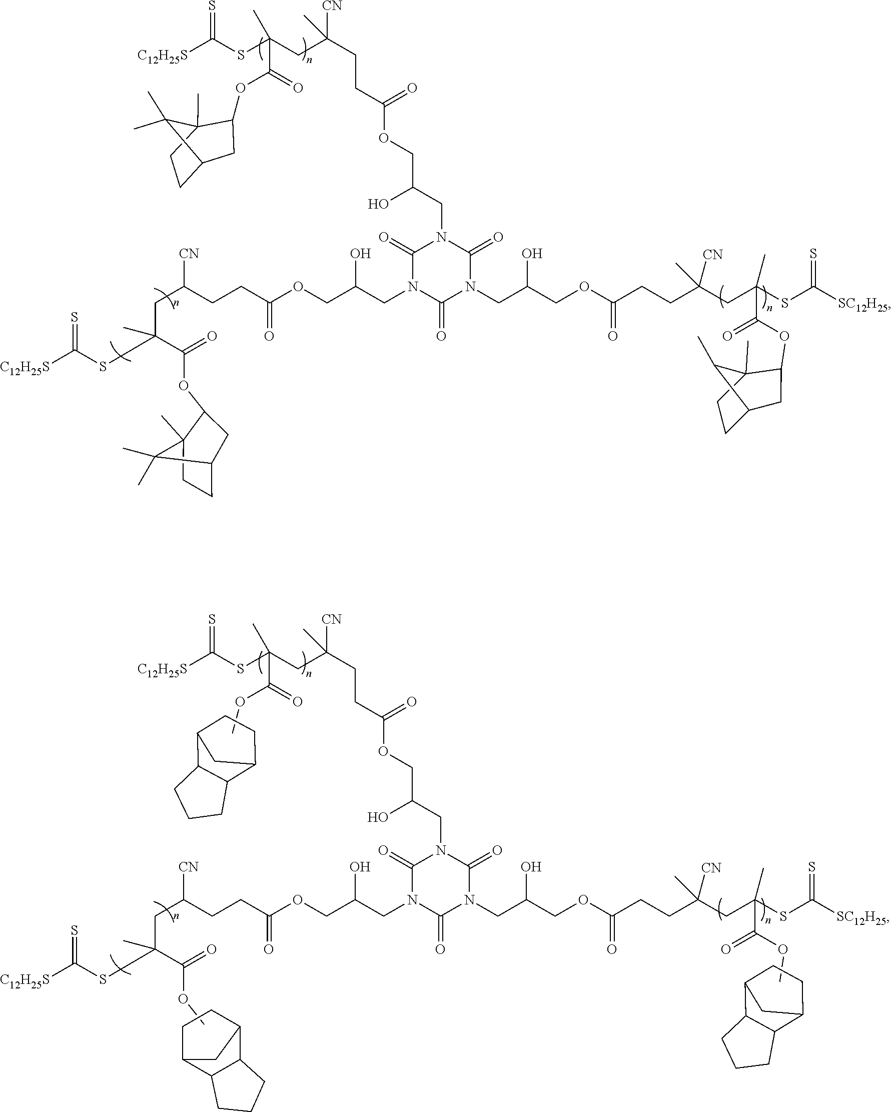

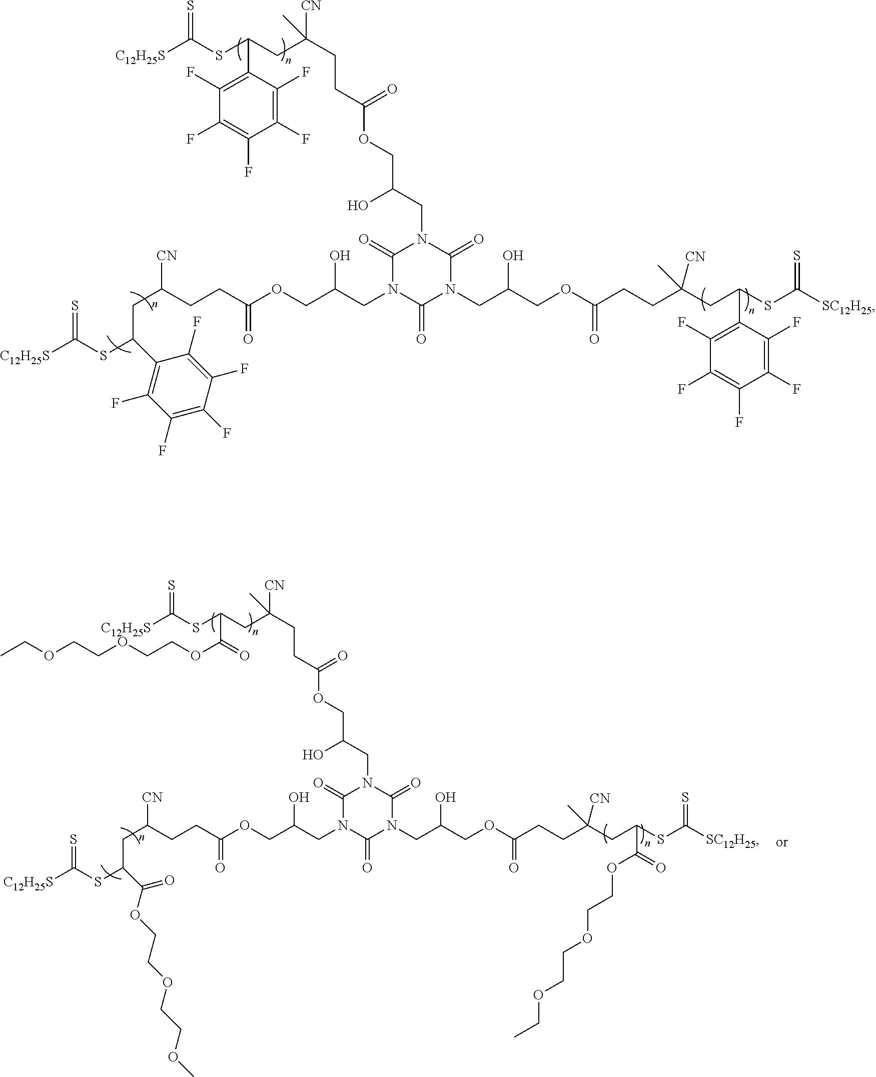

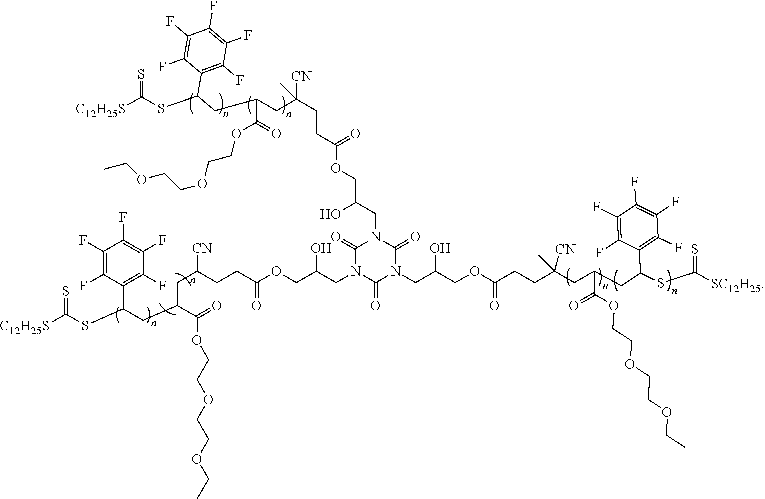

26. The microelectronic structure of claim 15, wherein at least one of the following is true:
said star macromolecule is PFAS-free;
said star macromolecule does not include any fluorine atoms;
said star macromolecule does not include any silicon atoms;
said star macromolecule does not include a metal phthalocyanine or moiety thereof; or
said star macromolecule does not include any iodine atoms.

27. A star macromolecule comprising:
a central core comprising wherein said central core comprises an isocyanurate moiety, a double-branched chain alkane moiety, a multifunctional polyether moiety, or combinations thereof; and
at least three arms radiating from said central core and each comprising at least two recurring monomers that can be the same or different and that are chosen from pentafluorostyrene, isobornyl methacrylate, dicyclopentanyl methacrylate, tert-butylstyrene, methylstyrene, fluorostyrene, 3,5-difluorostyrene, 2-(ethoxyethoxy)ethyl acrylate, 2-methoxyacrylate, methyl acrylate, 2-(ethoxyethoxy)methyl acrylate, 2-methoxymethacrylate, methyl methacrylate, or combinations thereof.

28. The star macromolecule of claim 27, wherein said star macromolecule comprises one of the following structures:

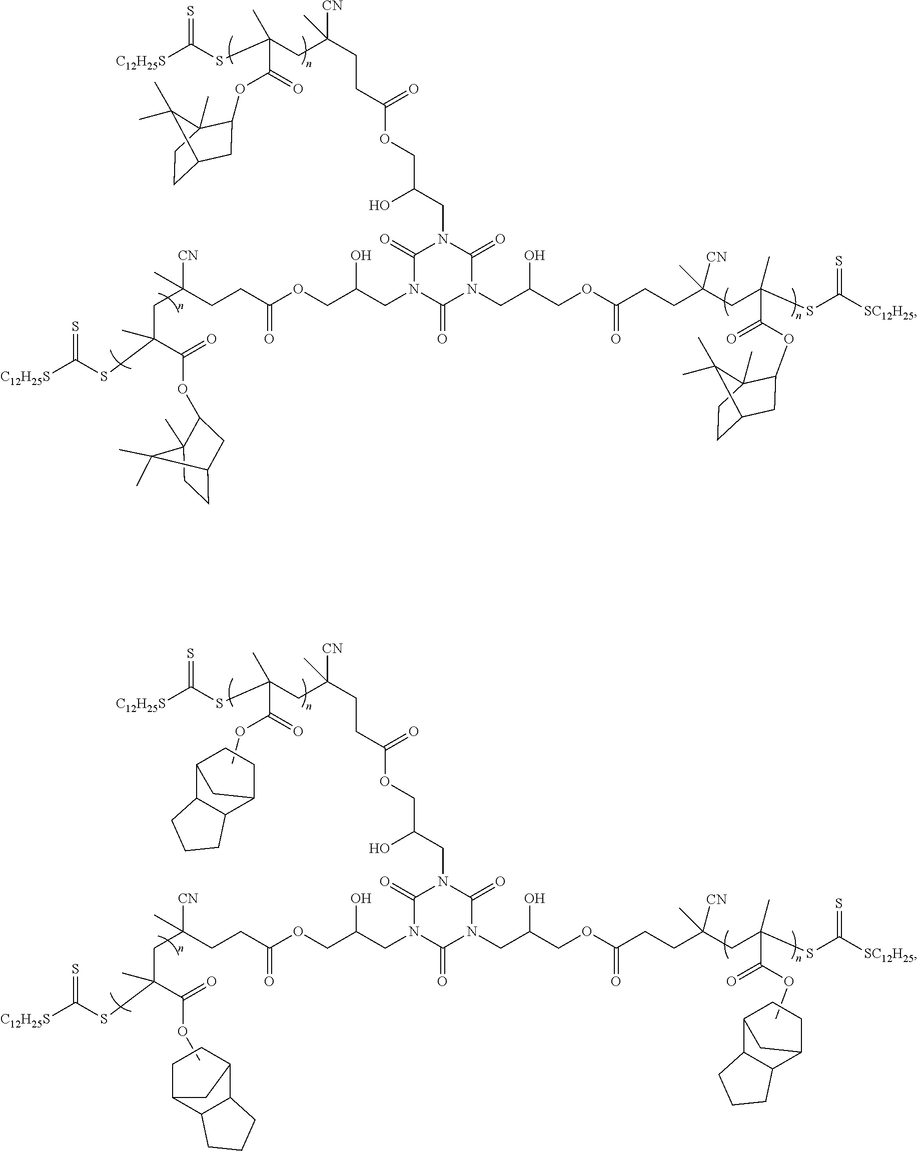

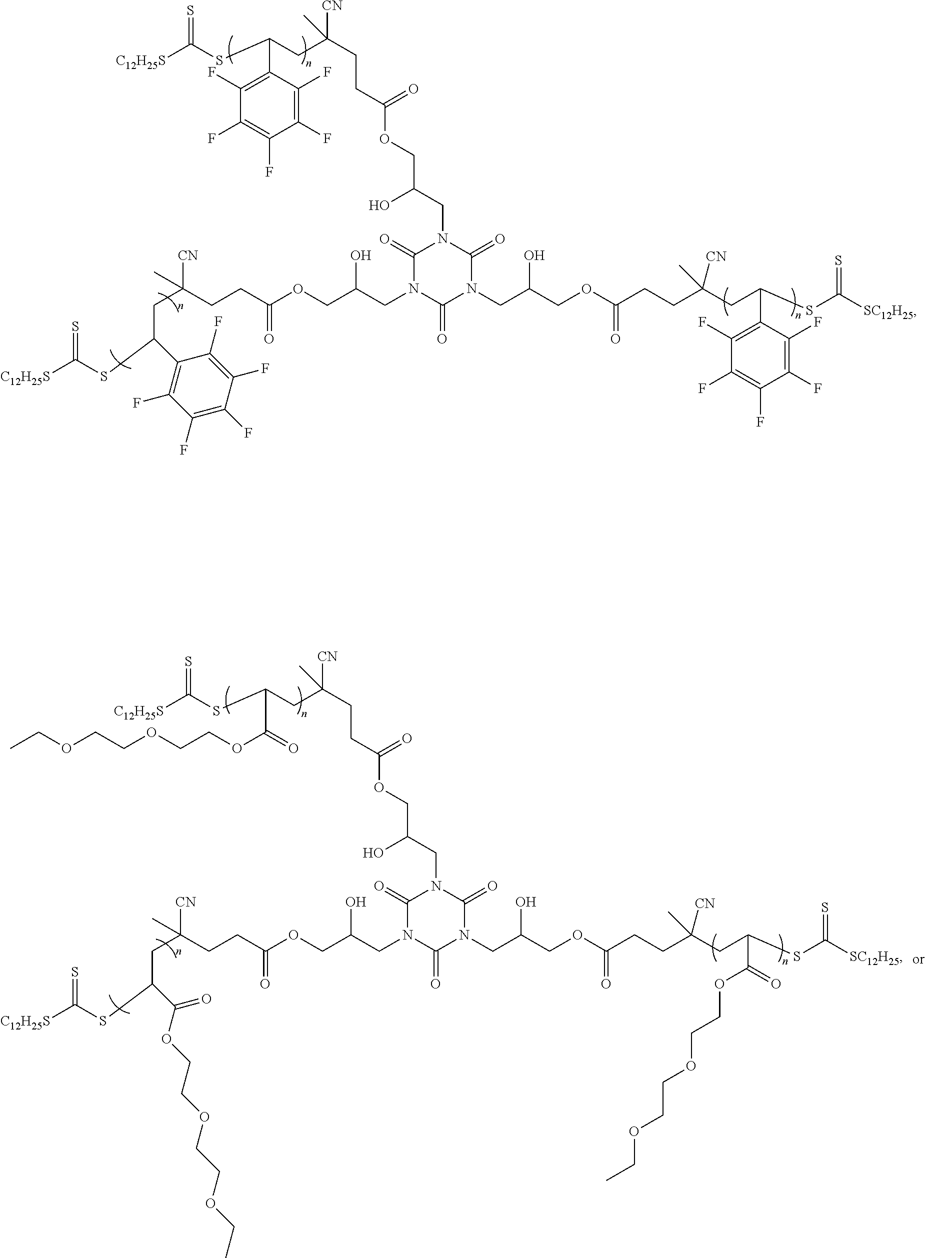

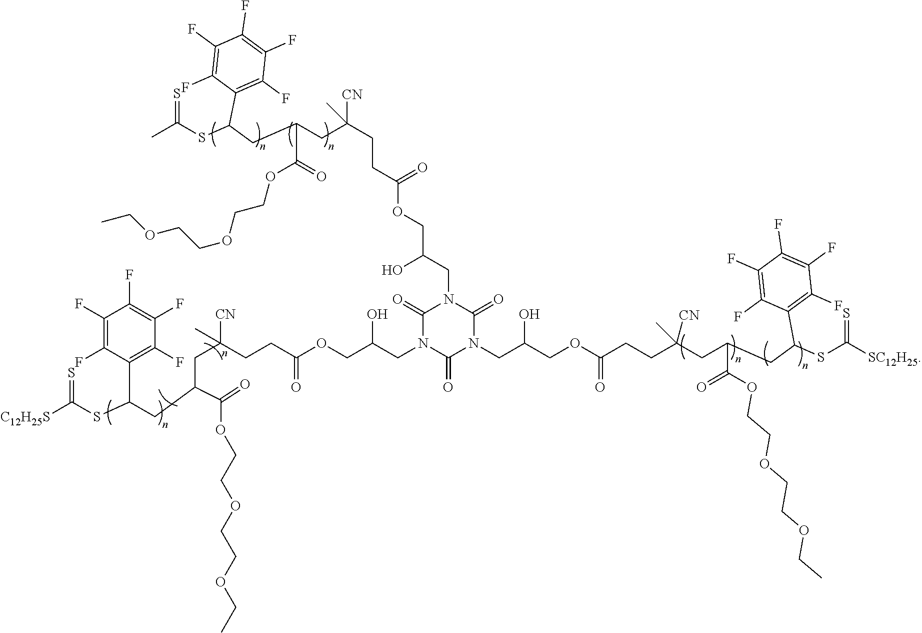

29. A composition comprising a star macromolecule according to claim 27, dispersed or dissolved in a solvent system.

30. The composition of claim 29, wherein said star macromolecule is present in said composition at a level of about 0.001% by weight to about 1% by weight, based on the total solids in the composition taken as 100% by weight.

31. The composition of claim 29, said composition further comprising a compound chosen from one or more of:
polymers and/or oligomers comprising monomers chosen from phenolic compounds, styrene, styrene-containing compounds, glycidyl-containing compounds, 2-hydroxyethyl methacrylate, hydroxypropyl methacrylate, hydroxybutylacrylate, silanes, siloxanes, or combinations thereof;
polymers chosen from polystyrene, functionalized polystyrene derivatives, polysulfones, polyethersulfones, poly(ether ether ketone), poly(vinyl naphthalene)), polycarbonates, epoxies, novolacs, polyimides, or combinations thereof, or
phenolic compounds, styrene, styrene-containing compounds, glycidyl-containing compounds, 2-hydroxyethyl methacrylate, hydroxypropyl methacrylate, hydroxybutylacrylate, silanes, or combinations thereof.

32. The composition claim 29, wherein said star macromolecule is PFAS-free.
